(19) United States
(12) Patent Application Publication
(10) Pub. No.: US 2015/0096488 A1
(43) Pub. Date: Apr. 9, 2015

(54) PREFERRED VOLUMETRIC ENLARGEMENT OF III-NITRIDE CRYSTALS

(71) Applicant: NITRIDE SOLUTIONS INC., Wichita, KS (US)

(72) Inventors: Peng Lu, Wichita, KS (US); Jason Schmitt, Wichita, KS (US)

(21) Appl. No.: 14/510,060

(22) Filed: Oct. 8, 2014

Related U.S. Application Data
(60) Provisional application No. 61/888,414, filed on Oct. 8, 2013.

(51) Int. Cl. C30B 23/00; C30B 29/40; C30B 23/02; C30B 25/16; C30B 25/18

(52) U.S. Cl. CPC C30B 23/002; C30B 25/16; C30B 25/186; C30B 23/025; C30B 29/403
USPC 117/94; 117/88; 117/84; 117/106; 118/720

(57) ABSTRACT

The present disclosure generally relates to systems and methods for growing and preferentially volumetrically enhancing group III-V nitride crystals. In particular the systems and methods include diffusing constituent species of the crystals through a porous body composed of the constituent species, where the species freely nucleate to grow large nitride crystals. The systems and methods further include using thermal gradients and/or chemical driving agents to enhance or limit crystal growth in one or more planes.

### RELATED APPLICATIONS

The application claims priority to U.S. Provisional Application No. 61/888,414, entitled “Preferred Volumetric Enlargement Of III-Nitride Crystals,” filed on Oct. 8, 2013; and is a continuation in-part to U.S. patent application Ser. No. 14/477,431, entitled “Bulk Diffusion Crystal Growth Process,” filed on Sep. 4, 2014, which claims priority to U.S. Provisional Application No. 61/873,729, entitled “Bulk Diffusion Crystal Growth Process,” filed on Sep. 4, 2013; each of which is incorporated herein by reference in their entireties.

### FEDERALLY SPONSORED RESEARCH OR DEVELOPMENT

N/A

### FIELD OF THE INVENTION/OVERVIEW

The present invention relates to the field of nitride semiconductor crystal substrates that can be used in the fabrication of larger nitride semiconductor crystal or electronic and or piezoelectric devices.

### BACKGROUND OF THE INVENTION

Volumetric growth in vapor phase crystal systems typically occurs by two methods. First, by the homogeneous nucleation of two-dimensional/three-dimensional nuclei on the growth surface; the so called island growth mode; and second by the surface diffusion of adatoms and subsequent attachment of adatoms into surface steps by so called step flow.

The volumetric growth of crystals is a function of both thermodynamics and kinetics, and can be controlled by altering growth conditions; growth temperature, temperature gradients, and chemical potentials.

C-plane platelet growth has been easily achieved in the SiC crystal system. See U.S. Pat. No. 2,854,364 to J. A. Lely, entitled Sublimation process for manufacturing silicon carbide crystals, issued 1958; W. F. Knippenberg, Growth Phenomena in Silicon Carbide, Philips Research Reports 18 (1963) 257; and A. A. Lebedeva et. al., Growth and investigation of the big area Lely-grown substrates Materials Science and Engineering: B46 (1997) 291. Each of these references reports on the ability to produce platelets with large c-plane surface areas. Yet no reports of other crystallographic platelets such as m or a plane have ever been reported for SiC growth. In fact it is assumed that the natural growth habits of hexagonal SiC only give rise to c-plane platelets. Thus inhibiting formation of other crystallographic-plane orientated platelets. The ability to produce C-plane SiC platelets repeatability set the foundation for the growth of the SiC electronics market. It has been found to be difficult to grow spontaneous nucleation of AlN single crystals that have the large facet parallel to the “c-plane” such as with SiC.

### SUMMARY OF THE INVENTION

The present disclosure generally relates to a novel systems and methods to control the growth of crystals and platelets. In particular, the present disclosure generally relates to systems and methods for growing group III-V nitride crystals and platelets, such as an aluminum nitride crystal, having a large c-plane or m-plane facet or lattice plane. The systems and methods include manipulating the volumetric growth of aluminum nitride in such a way that the c or m-plane is preferentially volumetrically expanded.

A chemical driving agent can be used with or without temperature gradients to control the preferential growth of AlN. Chemical driving agent species introduced during the growth changes the volumetric growth rate of the crystal producing large repeatable c-plane platelets at temperatures between 2000° to 2450° C. and m-plane crystals at temperatures between 2000 to 2450° C. not previously found.

The modification of aluminum nitride growth is not limited to the sublimation regime/method, nor is this process limited to AlN but is useful in the growth of ternary and more complex III-V compounds. The addition of additives, such as carbon, gallium, Indium, boron and carbon, gallium, Indium, boron bearing gases, into high temperature vapor phase epitaxy leads to preferential morphology control of the produced crystals also. Sulfur, Bismuth, and high volatility gases of Carbon, Indium, Gallium, Sulfur, Thallium, Magnesium, and Boron are useful in the lower temperature range (below 2200° C.) of these processes such as HVPE or High Temperature CVD growth.

In particular, the present disclosure relates to a method of preferably volumetrically enlarging a group III-V nitride crystal. The method includes providing a crystal growth structure and providing a crystal growth constituent, where the crystal growth constituent grows the group III-V nitride crystal on the crystal growth structure. The method also includes providing a chemical driving agent, where the chemical driving agent enhances or limits crystal growth on a particular plane of the group III-V nitride crystal.

In various aspects, the crystal growth structure is a substrate, a seed, or a previously grown-crystal. The crystal grown in accordance with the methods disclosed herein be substantially a single crystal or a platelet and may include nitrogen and at least one species of Al, Ga, and In. Moreover, one possible crystal that may be grown has a formula of AlxInyGa(1−x−y)N, where 0≧x≦1, 0≧y≦1, x+y+(1−x−y)≠1.

In one aspect, the chemical driving agent enhances growth of the previously grown-crystal from a first diameter to a second diameter without a corresponding growth in thickness. In another aspect, the chemical driving agent enhances growth of the previously grown-crystal from a first diameter to a second diameter without inducing thermal stress into the previously grown-crystal.

In one embodiment a method of preferably volumetrically enlarging a group III-V nitride crystal includes providing a crystal growth structure and providing a crystal growth constituent, where the crystal growth constituent grows the group III-V nitride crystal on the crystal growth structure. The method includes providing a chemical driving agent, where the chemical driving agent enhances or limits the mobility of a crystal growth constituent adatom at a growth surface of the group III-V nitride crystal. In one aspect, the crystal growth structure is disposed within in a reactor system and the chemical driving agent alters the surface growth kinetics of the reactor system.

In another embodiment, a method for growing and preferably volumetrically enlarging a group III-V nitride crystal includes providing a powder to an annular-shaped cavity of a crucible. The annular shaped cavity is defined by an interior surface of the crucible and a packing tube removably disposed in the crucible. The powder includes a distribution of particle sizes of at least one constituent species of the group III-V nitride crystal.

The method also includes compressing the powder to form a charge body, removing the packing tube to form a charge body cavity, where the charge body includes an exterior surface and an interior surface defining the charge body cavity. The crucible is heated to sinter the charge body. Heating the crucible further induces a thermal driving force across the charge body. The method also includes providing a chemical driving agent and soaking the crucible and the charge body at a temperature sufficient to diffuse the at least one constituent species of the group III-V nitride crystal from the exterior surface to the interior surface of the charge body. The at least one constituent species of the group III-V nitride crystal freely-nucleates in the interior surface to grow the group III-V nitride crystal in the interior cavity. The chemical driving agent enhances or limits crystal growth of the group III-V nitride crystal on a particular plane of the group III-V nitride crystal.

In another embodiment, a system for growing and preferably volumetrically enlarging a group III-V nitride crystal includes a reactor, a crucible, a chemical driving agent source, and a sintered porous body disposed with in the crucible. The sintered porous body includes an exterior surface, an interior surface defining an interior cavity and at least one constituent species of the group III-V nitride crystal.

The reactor heats the crucible to form a thermal driving force across the sintered porous body and the thermal driving force diffuses the at least one constituent species of the group III-V nitride crystal from the exterior surface to the interior surface. The at least one constituent species of the group III-V nitride crystal freely-nucleates in the interior surface to grow the group III-V nitride crystal in the interior cavity. The chemical driving agent enhances or limits crystal growth of the group III-V nitride crystal on a particular plane of the group III-V nitride crystal.

### BRIEF DESCRIPTION OF THE DRAWING

FIG. 1 includes perspective and top views of three typical crystallographic-plane orientations associated with the wurtzites hexagonal crystal system.

FIG. 2 is a photograph showing the natural growth habits of AlN for sublimation from 1800° C. through the melting point of approximately 2450° C.

FIG. 3 is a photograph showing an m-plane AlN crystal grown using only isothermal controls, according to one embodiment.

FIG. 4 is a cross-sectional view of a crucible packed with a charge and packing tube according to one embodiment.

FIG. 5 is a cross-sectional view of a crucible packed with a charge and a packing tube according to one embodiment:

FIG. 6 is a cross-sectional view of a crucible and a charge body disposed therein, according to one embodiment.

FIG. 7 is a cross-sectional view of a reactor for growing crystals on a charge body according to one embodiment.

FIGS. 8A-C are cross-sectional views of a crucible and a charge body disposed therein, and methods for introducing a chemical driving agent to the crucible according to various embodiments.

FIG. 9 is a cross-sectional view of crystals grown on a depleted charge body according to one embodiment.

FIG. 10 includes photographs of crystals grown in accordance with various embodiments.

FIG. 11 is a cross-sectional view of a depleted charge body with crystals grown thereon during a recharging process according to one embodiment.

FIG. 12 is a cross-sectional view of crystals grown on a multi-layered charge body according to one embodiment.

FIG. 13 is a cross-sectional view of a crucible and charge body with a porous second body disposed therein according to one embodiment.

FIG. 14 is an illustration of c-plane platelet growth on a charge body according to one embodiment.

FIG. 15 is an illustration of m-plane platelet growth on a charge body according to one embodiment.

FIG. 16 is a cross-sectional view of a crucible and charge body with through holes disposed therein according to one embodiment.

FIG. 17 is a cross-sectional view of a crucible and charge body with a porous second body with gas supply tubes disposed therein according to one embodiment.

FIG. 18 includes cross-sectional views depicting crystal c-plane growth both in the absence and in the presence of a chemical driving agent according to one embodiment.

FIG. 19 includes cross-sectional views depicting crystal m-plane growth both in the absence and in the presence of a chemical driving agent according to one embodiment.

FIG. 20 is a cross-sectional view depicting a system for growing crystals using a sublimation technique, according to one embodiment.

FIG. 21 depicts various crystal structures grown under different thermal gradients at the crystal surface, according to one embodiment.

FIGS. 22A-B are cross-sectional views depicting crystal growth under thermal gradients both in the absence and in the presence of a chemical driving agent according to one embodiment.

FIGS. 23A-B are cross-sectional views depicting crystal growth under isothermal or near isothermal conditions both in the absence and in the presence of a chemical driving agent according to one embodiment.

FIG. 24 includes cross-sectional views are thermal gradients and a chemical driving agent are used in conjunction, according to one embodiment.

FIG. 25 includes cross-sectional views depicting horizontal crystal growth followed by vertical crystal growth in response to changes to a chemical driving agent according to one embodiment.

FIG. 26 includes cross-sectional views depicting vertical crystal growth followed by horizontal crystal growth in response to changes to a chemical driving agent according to one embodiment.

FIG. 27 includes cross-sectional views depicting horizontal crystal growth followed by vertical crystal growth in response to changes to a chemical driving agent according to one embodiment.

FIG. 28 includes cross-sectional views depicting horizontal crystal growth followed by vertical crystal growth in response to changes to a chemical driving agent according to one embodiment.

### DETAILED DESCRIPTION

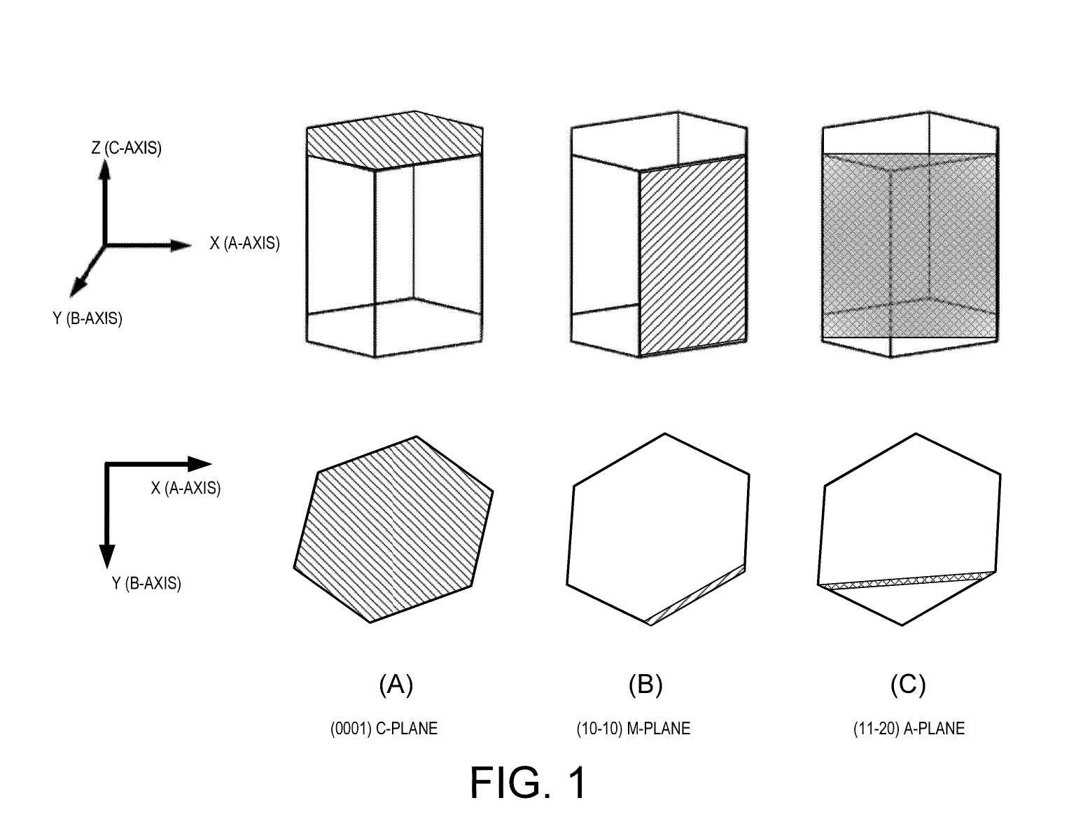

Group III-Nitride crystals of AlN, GaN, and SiC are most stable in the wurtzite crystal structure shown in FIG. 1. Three typical crystallographic-plane orientations are associated with wurtzites hexagonal crystal system. These include the c-plane 101 (e.g., the (0001) plane), the m-plane 103 (e.g., the (10-10) plane), and the a-plane 105 (e.g., the (11-20) plane). When the growth of flat crystals with one large predominate crystallographic-plane and with all other crystallographic-planes truncated occurs these crystals are known as platelets. Platelet growth can occur theoretically on any crystallographic-plane within the hexagonal crystal structure, but there are practical limitations upon platelet formation.

It was found that the production of the c-plane aluminum nitride platelets like those found in SiC were impossible. As reported in Natural Growth Habit of Bulk AlN Crystals, B. M. Epelbaum, Journal of Crystal Growth 265 (2004) 577, the attempts to form SiC like platelets resulted in thick asymmetrical platelets that showed many un-preferred crystal facets. During the investigation of AlN, crystal platelet thickness varied from 1 to 3 mm, but habit facets that governed the asymmetric appearance were “omnipresent”. In Development of natural habit of large free-nucleated AlN single crystals, B. M. Epelbaum et. al., physica status solidi (b) 244, No. 6, 1780-1783 (2007), it was reported, “The platelet crystals exhibit characteristic asymmetric habit with largest flat being a pseudo-facet build by alternating (1010) facets. Pronounced true facets are Al-terminated (0001) and adjacent (1012) facets, with one of them growing much larger than others. The analysis of formation history of freestanding AlN crystals made it possible to explain their habit, very unusual for wurtzite-type structure. Growth of freestanding AlN starts from a long needle formed along the (11-20) direction at lower temperature of 1900-2000° C. and continues by needle expansion and thickening along mainly (0001) direction, leading to asymmetric platelet. In such geometry only one extended (1012) facet can be developed.” It further stated, “The growth model presented here provides an answer to the curious habit of freestanding AlN based on the analysis of its growth history. The model explains specific zonar structure of freestanding AlN as well.” The perceived problems with producing freely nucleated c-plane AlN platelets in comparison to SiC platelets are also noted in Similarities and differences in sublimation growth of SiC and AlN, B. M. Epelbaum et. al., Journal of Crystal Growth 305 (2007) 317.

Very small, unintentional, freely nucleated multi m-plane/a-plane AlN crystals have been observed as a byproduct of other AlN production methods. Unfortunately morphological control to produce one dominant platelet surface and reproducibility of these platelets has proved difficult if not impossible. It has also been reported that some “spontaneously nucleated crystals exhibited an incomplete pyramid-like structure with (10-10) and (1100) as their prominent faces,” in Sublimation growth of AlN bulk crystals by seeded and spontaneous nucleation methods, K. Balakrishnan et. al., Materials Research Society (MRS) Proceedings, volume 83, 2004.

The ability to control and manipulate the growth habits of III-Nitride crystal systems, including but not limited to the crystallographic-planes and the volumetric growth, especially that of AlN and SiC, is crucial in the commercial production of these crystal systems. The m-plane surface is used in non-polar laser diode and other optical devices where the c-plane is preferred for polarization enhanced electrical devices and power electronics.

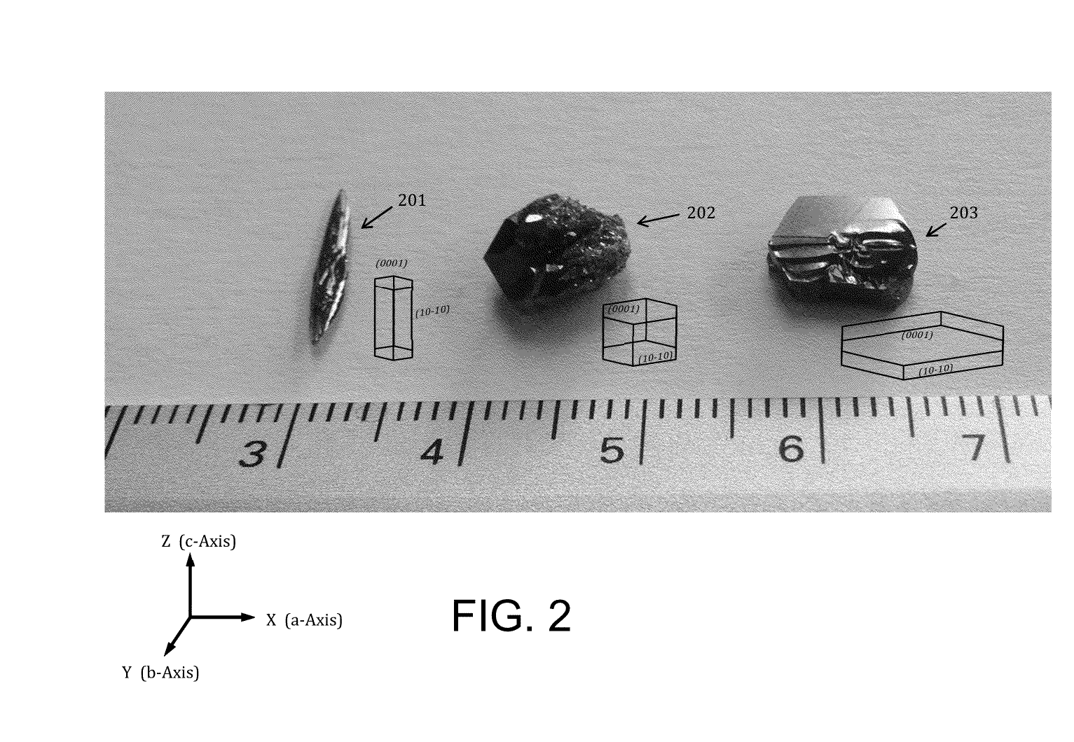

It has been now shown that spontaneously nucleated AlN crystals follow a sequence of natural volumetric growth as shown in FIG. 2. AlN grows from needles (where the dominate growth is normal to the c-plane leading to long crystals with high aspect ratios) to a thicker 3-D near symmetric bulk (where growth normal to the c-plane has been slowed and growth in the m-plane is increased to a point where the they are nearly equal), and finally to thin symmetric platelets where the growth is greater normal to the m-plane then normal to the c-plane as seen in SiC, as disclosed in U.S. patent application Ser. No. 14/477,431, entitled “Bulk Diffusion Crystal Growth Process,” by Schmitt et. al., filed on Sep. 4, 2014. This evolution progresses with increasing growth temperatures up to and over 2400 C. The growth habits of AlN have been observed for sublimation growth regime and at lower temperature, below 2000° C. or so, the growth rate is higher perpendicular to the c-plane. This leads to what is called needle growth 201. With increases in temperature, to above around 2100° C., the growth rate of the perpendicular and parallel directions (c-plane and m-plane) evens out and the growth becomes more of a symmetric 3-D shape 202. As the temperature is raised to over 2370° C. the growth parallel to the c-plane begins to overcome the growth rate of the perpendicular growth. At temperature above 2400° C., very flat AlN platelets 203 can be made, as growth perpendicular to the c-plane is slowed as the temperature is increased.

As disclosed in, the co-pending parent application the c-plane of the AlN system will align itself along the isotherms of the growth environment it is in. Or, in other words, the c-plane will align itself perpendicular to the largest temperature gradient inside the growth environment. In the growth environment the direction the isotherms take can be controlled. Changing the insulation and relative position of the crucible inside the reactor achieves this control over the isotherms.

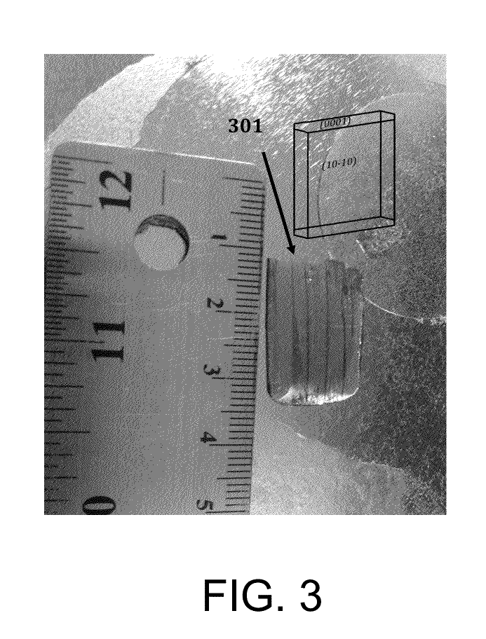

In a method to growth freely nucleated AlN crystals disclosed in the co-pending parent application, it was disclosed that after loading a charge into a crucible growing crystals therein, preventing growth in the 3-D growth regime, as shown by the 3-D crystal 202, is desired. In the 3-D growth regime, pits or holes are formed in the surface parallel to the charges surface as the crystal expanse volumetrically. This is due to nanostructures formed during nucleation and a shadowing effect where the concentrations of the Al and N species change dramatically across the shadowed surface. If the nanostructures formed during nucleation on the charge or shadowing occurs on a surface that is the polar c-plane, it can cause changes in the polarity of the crystal during growth. Thus, in the present disclosure it is desirable to set or otherwise control the nanostructures formed during nucleation on the charge wall and keep the crystal growth in a near 2D growth mode where the c-plane is the dominant facet, when producing c-plane seeds and platelets 203. In the 3-D growth regime the pits or holes formed in the c-plane surface make these crystals undesirable for c-plane substrates; however a portion of the m-plane may be used. To produce m-plane crystals 301, as shown in FIG. 3, where the m-plane is the dominant facet, it is also desirable to limit the crystal's growth in a near 2D growth mode and to set the nanostructures formed during nucleation on the charge.

It has also been disclosed in the co-pending parent application, that by holding the isotherms horizontal, using isothermal horizontal thermal gradients, inside the crucible, it forces the c-plane to expand perpendicular to the charge's surface. Conversely if m-plane crystals and/or seeds are to be produced, the c-plane is set perpendicular to the charge surface. The thermal fields are changed such that the thermal gradient from top to bottom is held isothermal and a larger gradient is introduced across or radial to the crucible.

The present disclosure further relates to systems and methods of crystal growth where temperature alone is not the desired driver for AlN morphology. In various embodiments, this is accomplished by spatially confining the height of the crucible. By way of example and not limitation, the crucible height may in a range of approximately 1 mm to 3 mm, where single crystals having dimensions as large as approximately 15 mm×25 mm by 1 mm thick, shown in FIG. 3, are produced.

While relying on temperature alone may make producing m-plate AlN crystals difficult, temperature used to control the growth morphology has produced good c-plane platelets in temperatures ranging from 2380-2420° C., as shown in FIG. 3. But the process window for producing the platelets is very narrow. This allows little to no allowances for the production of nonpolar m-plane platelets.

As an alternative to temperature modifications, using a chemical driving agent has been identified as a way to obtain preferential morphology control across a wide temperature regime to control preferential volumetric growth. As used herein “preferred volumetric enlargement” refers to the controllable and desired growth of a crystal structure in one or more specific planes or directions. In various embodiments, carbon is used as a chemical driving agent for forcing the AlN morphology into the c-plane platelet regime at temperatures below its natural occurrence at approximately 2400° C. Furthermore, there is a strong correlation between the concentration of the driving agent in the system and the effects on the system. For example, increasing carbon concentrations leads to increased anisotropic growth rates normal to the m-plane and c-plane, leading to thinner platelets with a large c-plane surface.

In various embodiments, the driving agent may be the gas species of carbon (C), gallium (Ga), indium (In), sulfur(S), bismuth (Bi), Boron (B), magnesium (Mg), titanium (Ti,) silicon (Si), or combinations thereof. The driving agent agents may be used in elemental form or as compounds containing one or more elements. When adsorbed on the surface of an AlN crystal, the driving agent changes the surface energy, diffusion method and diffusion length of the Al and or N adatoms on the surface. This will increase the rate of formation of stable two-dimensional AlN nuclei on certain growth facets and thus changes the volumetric growth rate of the crystal along those facets.

For chemical driving agents, such as carbon and silicon, increasing the concentration at the surface increases the change in the volumetric growth rate. However, a large amount of carbon and silicon introduced during the growth can incorporate into the crystal system and change the optical and electrical properties of the crystal. Thus, it is desirable to use a chemical driving agent that will not readily incorporate into the aluminum nitride crystal. In various embodiments, gallium, indium, and bismuth, alone or in combination, can be used to preferentially control the morphology of aluminum nitride to produce large c-plane platelets at temperatures between approximately 1800 and 2450° C. In these embodiments, it is believed that indium and gallium affect the surface energy, diffusion method and diffusion length of the Al and or N adatoms but do not significantly incorporate, to the same extent as carbon and silicon, into the aluminum nitride crystal lattice at temperatures above 1800° C. This is due, at least in part, to their higher vapor pressure and low sticking coefficients.

In various other embodiments, chemical driving agents may be used in conjunction with temperature gradients to promote and control crystal growth. For example, the addition of Boron as a chemical driving agent along with controlling the thermal profile during crystal growth can increase the rate of formation of stable two-dimensional AlN nuclei on the m-family growth planes and thus change the volumetric growth rate of the crystal along those facets. This leads to the formation of thin m-plane crystals platelets at temperatures where such growth has not been previously observed. For example, the combined use of thermal gradients and Boron as a chemical driving agent permitted the growth of thin m-plane crystals at temperatures between approximately 2000 to 2450° C.

As disclosed herein, the modification of aluminum nitride crystal growth is not limited to systems and methods that rely on sublimation. In various embodiments, the addition of additive chemical driving agents, such as carbon, gallium, Indium, boron or gases including the aforementioned elements, among others, into high temperature vapor phase epitaxy systems also leads to preferential morphology control of the produced crystals. In these embodiments, Sulfur, Bismuth, and high volatility gases of Carbon, Indium, Gallium, Sulfur, Thallium, Magnesium and Boron are useful in low temperature (below 2200° C.) growth processes, such as but not limited to HVPE or High temperature CVD growth.

The systems and methods disclosed herein are not limited to growing AlN but are useful in the growth of ternary and more complex III-V compounds. For example, HVPE may be used to grow aluminum gallium nitride (AlGaN) crystals having preferred morphology at growth temperatures as low as about 1000° C. In these examples, the chemical driving agents may include hydrocarbons, indium, sulfur, bismuth, and diborane, among others.

In various embodiments, the chemical driving agents may be any suitable form, type, phase of matter or physical composition of material. Alternately, any suitable precursor compound or compounds that will produce the desired chemical driving agent or agents in situ maybe used to promote preferential volumetric growth. For example, Gases, solids, open porous volume foams, powders, liquids, phase changing systems, or any other volatile or nonvolatile compound containing the desired chemical driver agent elements can be used, including oxides. As understood by one skilled in the art, these materials could be placed in proximity to the crystal growth \surface, intermixed within any starting material or gas stream used to produce the III-N crystal, incorporated into structural support or non-supporting structural components in a suitable reactor system. For example, chemical driving agent or precursors thereof may be incorporated into or positioned proximal to thermal insulation, support structures, crucibles, and/or retorts.

In various embodiments, the chemical driving agent may be used or otherwise activated to preferentially and volumetrically augment crystal at will. For example, the crystals exposure to the chemical driving agent may be toggled on and off or ramped up during the growth. In other examples, the concentration, volume, time of exposure, and other parameters related to the deployment of the chemical driving agent may be varied. In one particular example, a solid chemical driving agent may be used in conjunction with a gaseous driving agent, such that the application of the gaseous driving agent may be modified or even stopped to provide varied combinations for the chemical driving agents deployed. This allows for the preferential volumetric expansion in one plane until a desired size or volume expansion has been achieved. The growth direction may then be altered by promoting growth in a different plane using thermal gradients, chemical driving agents, or both. In one embodiment, this is accomplished, by reducing or eliminating one chemical driving agent thus permitting non-preferential volumetric expansion.

In other embodiments, by toggling between different agents (e.g., introducing second agent that will preferentially volumetrically expand the crystal in another plane) preferential three-dimensional growth can be obtained. For example, this may be accomplished by switching between a carbon based driving agent and a boron-based driving agent. In this example, a carbon containing gas, giving preferential volumetric expansion in the c-plane, is introduced into a system for growing crystals using HVPE. A boron containing gas, giving preferential volumetric expansion in the m-plane, may then be used. Moreover, one driving agent component may be a passive solid such as, a solid source of carbon, and the other agent may be a boron containing gas that can be actively modified, during the growth process.

In another embodiment, a chemical driving agent, such as Carbon and/or Boron, can be employed in a sublimation reactor in a two-step process to first expand out (in diameter) a AlN seed crystal on a preferred lattice plane then second grow down (in length) on that same lattice plane or another plane. In similar embodiment, at least two growth regimes may be used. One growth regime preferentially grows the crystal along one plane, while the second growth regime preferentially grows in the crystal on another plane by: 1) changing the thermal fields in the presence of a chemical driving agent; 2) changing the chemical driving agents in the presence of a static thermal profile; or 3) changing both the chemical driving agent and the thermal profile during the growth. This can be accomplished in separate processes where the crystal is heated and grown under one regime, cooled down and repositioned for growing under the second regime. Alternatively, the both regimes may be used concurrently little or no changes in the thermal fields. The growth regimes may be deployed in a discreet cyclic manner or the transitions between the two regimes can be identified by a smooth gradient change from one driving agent concentration to another or from one thermal profile to another.

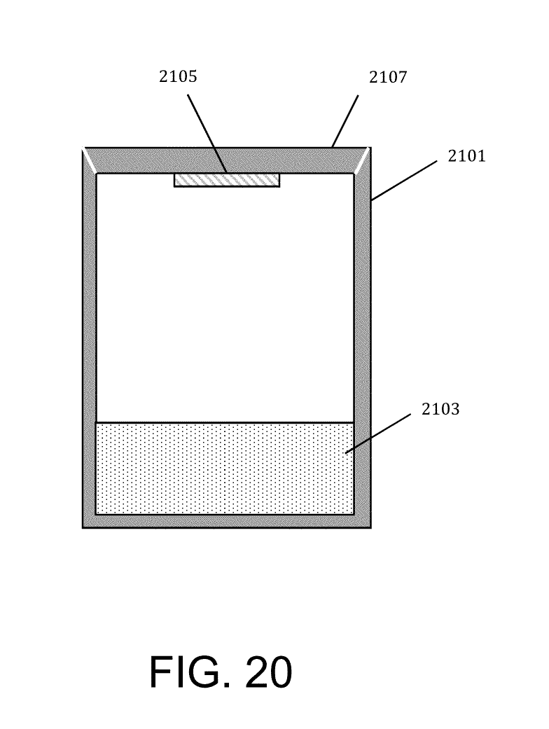

In one embodiment of growing crystals using a sublimation technique, shown in FIG. 20, three factors are provided to affect crystal growth. The first factor is a temperature gradient that is a 3-dimensional component of the vertical and horizontal isotherms. The second factor is the chemical concentration of a chemical driving factor which has a two-dimensional flux at the crystal growth surface. The third factor is the effect of the chemical driving agent. In sublimation growth, where isotherms cannot be sufficiently controlled, the use of one or more chemical driving agents to even out temperature and concentration fluctuations inside the growth crucible is desired.

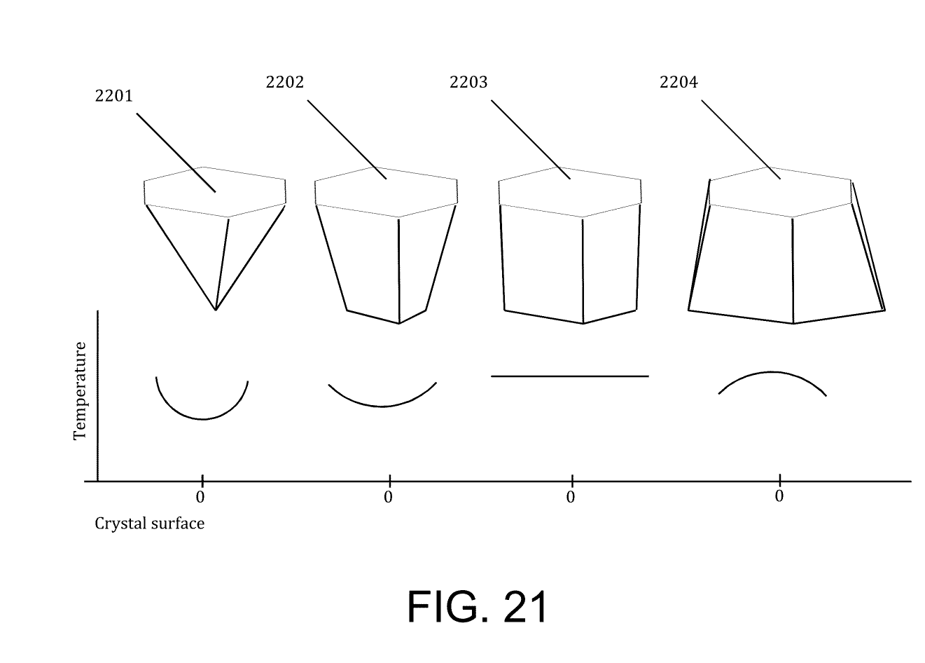

When considering the first and third factors, it has been determined that changes in the X-Y-Z temperature gradient and the X-Y concentration of the driving agent species gradient can modify the growth habits of the crystal, as shown in FIG. 21. For example, when the temperature isotherms are strongly concave normal to the c-plane they result in a smaller crystal diameter, indicated as 2201, as the crystal grows along the Z direction. As the temperature isotherms flatten out the crystal becomes less tapered, shown as 2202 until it is flat and the crystal growth is parallel to the z direction, and indicated as 2203. If the temperature isotherms are inverted such that it is concave at the crystal surface, the crystal will grow angled out and expanded its size, as shown as 2204. As shown, the flatter the temperature isotherms at the surface, the less stress that is introduced into the crystal.

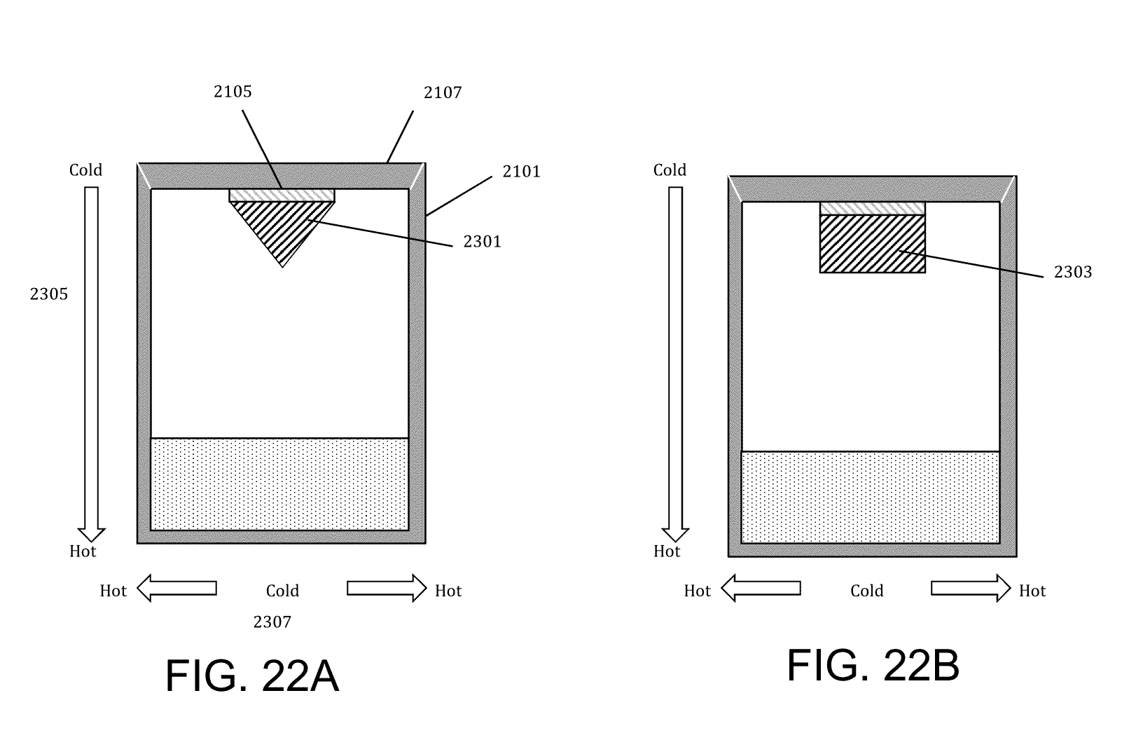

In typical growth normal to the c-plane without chemical driving agents, as shown in FIG. 22A, the nitride crystal tends to shrink as it grows and converges towards a point. This is primarily due to the lack of an isothermal and homogenous chemical concentration environment across the surface of a wafer, generally indicated by 2307. As shown, the X-Y plane temperature gradient is colder near the center of the crystal surface and hotter near the outside edges, resulting in a greater growth rate in the center of the crystal than that at the edges resulting in the crystal growing towards a point. It is difficult to control the concentration of the Al and N species across the wafer to regulate the growth rate as the temperature gradient alters the chemical concentration. This non-even growth may induce stress into the crystal. Therefore, the addition of chemical driven agents counteracts the lack of temperature uniformity across the X-Y plane by limiting the growth rate of the crystal and/or increasing surface adatom migration.

When used in appropriate quantities, the chemical driving agents act as a buffer thereby evening out or nullifying the temperature gradient, thus resulting in more uniform crystal growth as shown in FIG. 22B.

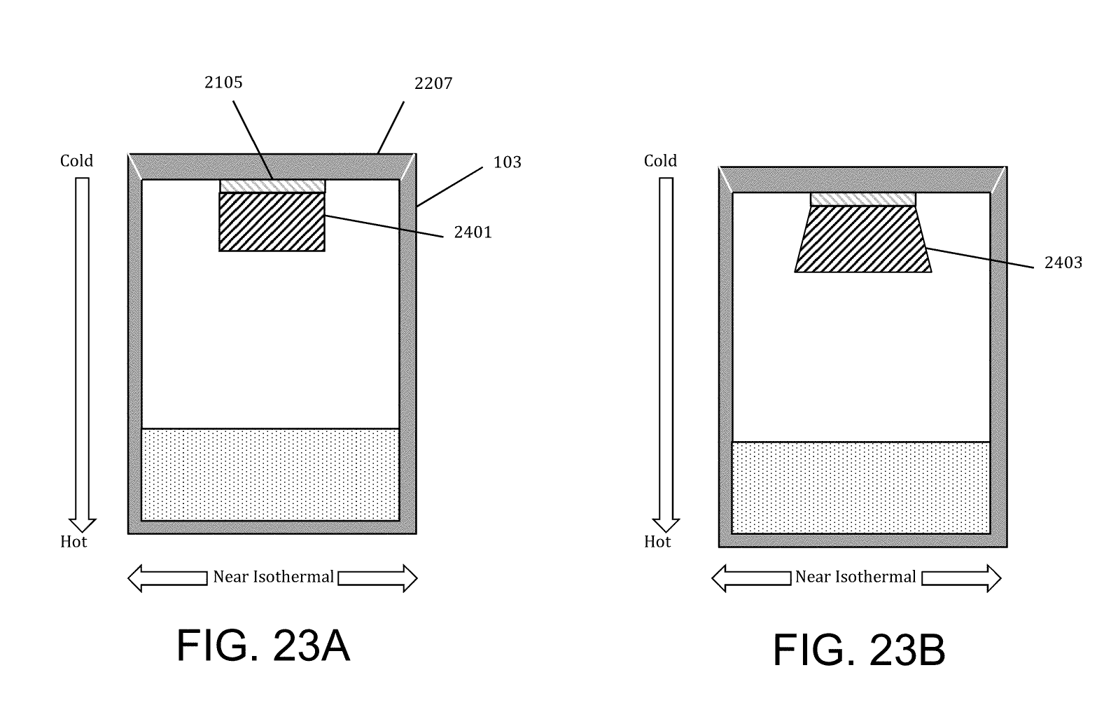

Typically, expansion of the AlN crystal diameter during sublimation growth is brought about by using a concave temperature profile, shown by 2204 in FIG. 21. As previously noted, such a temperature profile may induce unwanted stress into the crystal. According to various embodiments, this type of growth can be achieved, however, without aggressive thermal profiles by incorporating chemical driving agents, as shown in FIGS. 23A-B. FIG. 23A shows an example crystal grown at or near isothermal conditions. As the concentration of the chemical driving agent is increased to the point where the chemical effect offsets the temperature gradient in the X-Y plane, preferentially increases in the diameter of the wafer, as indicated by 2403 in FIG. 23B, can be obtained without the use of high stress-inducing temperature profiles.

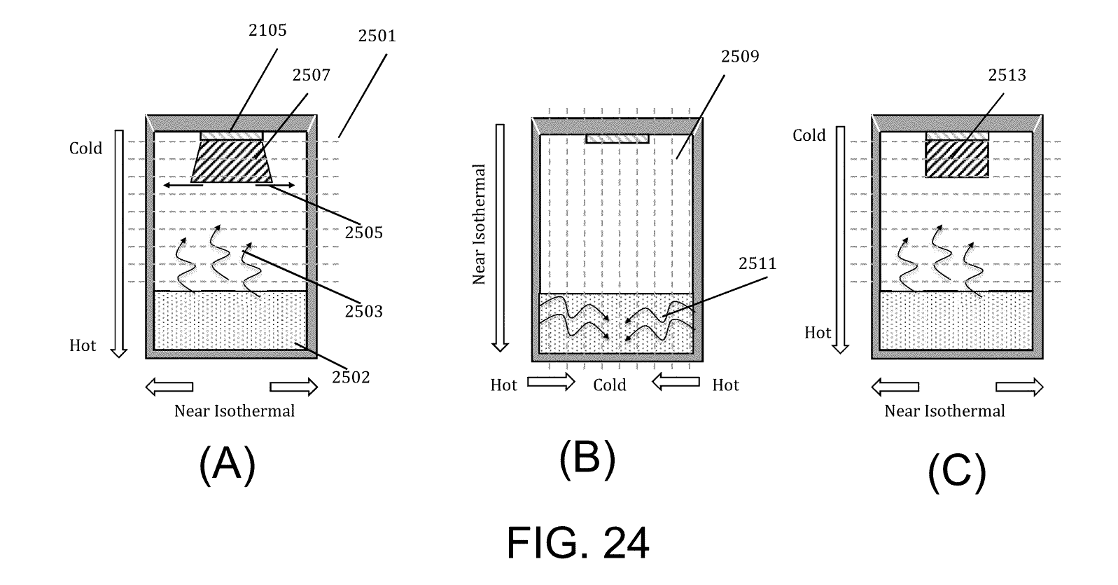

For growth perpendicular to the m-plane, the addition of chemical driving agents such as carbon can be used to offset the need to control the isotherms. As shown in FIG. 24, the isotherms 2501 are set flat in the X-Y plane to promote sublimation growth in the Z direction for c-plane AlN. This allows for good material transport 2503 from an AlN source powder 2502 up to the seed crystal 2105. Unfortunately, these isothermal lines are in direct contrast to the natural growth habit of m-plane AlN. Therefore, during sublimation growth stress, generally indicated as 2505, is introduced into the crystal 2507 from the forced growth in the c-plane aligned to the isotherms 2501. This stress has been show to crack the m-plane crystal produced. To counter, the issue of forced expansion growth, the isotherms 2509 are set isothermal in the z direction, as shown in (B). This promotes growth downward in the Z direction of the M-plane crystal but also forces the transport of AlN 2511 to become parallel and not perpendicular to the m-plane seeds surface ultimately stopping the transport of source material to the surface of the m-plane seed 2105 drastically reducing if not stopping growth rate. In various embodiments, adding chemical driving agents at sufficient concentrations to the AlN powder source 2502 makes it possible to grow an ingot of m-plane AlN 2513 from an m-plane AlN seed 2105. In one aspect, the addition of the carbon as the chemical driving agent stabilizes the growth normal to the m-plane.

### Example Methods of Growing and Preferred Volumetric Enlargement of Crystals

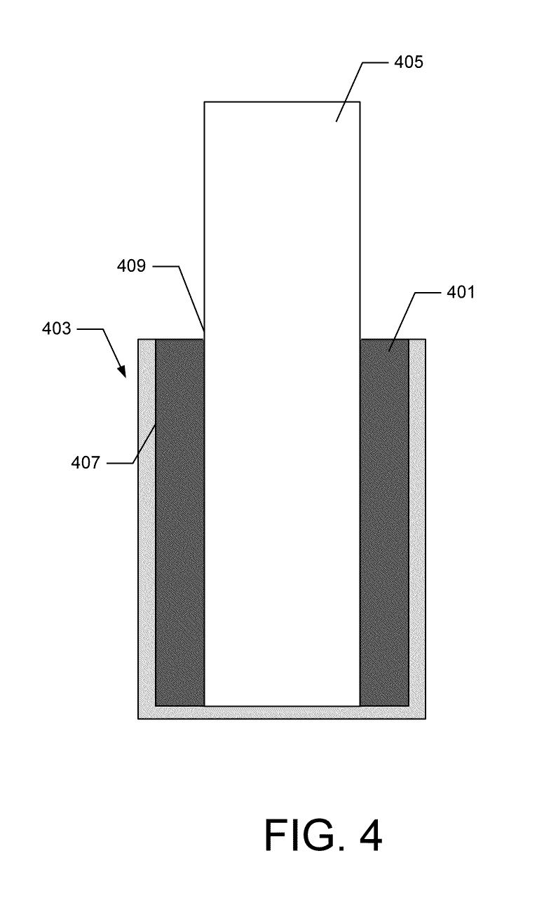

Referring now to FIGS. 4-6, a crucible 403 suitable for use within a high-temperature reactor is filled with a charge 401. The charge 401 is typically a solid that is disposed within the crucible and forming a porous body. In one embodiment, the charge 401 is composed of AlN (AlN) powder. The particle size of a powder charge 401 may be in a range between 0.01 microns and 10 mm. In one embodiment, the particle size of the charge 401 may be uniform, alternately in another embodiment the particle size may vary such that the charge is composed of a distribution of different size particles. In one embodiment, the charge 401 is composed of AlN powder having a distribution of particles in a range between 0.1 microns to 1 mm.

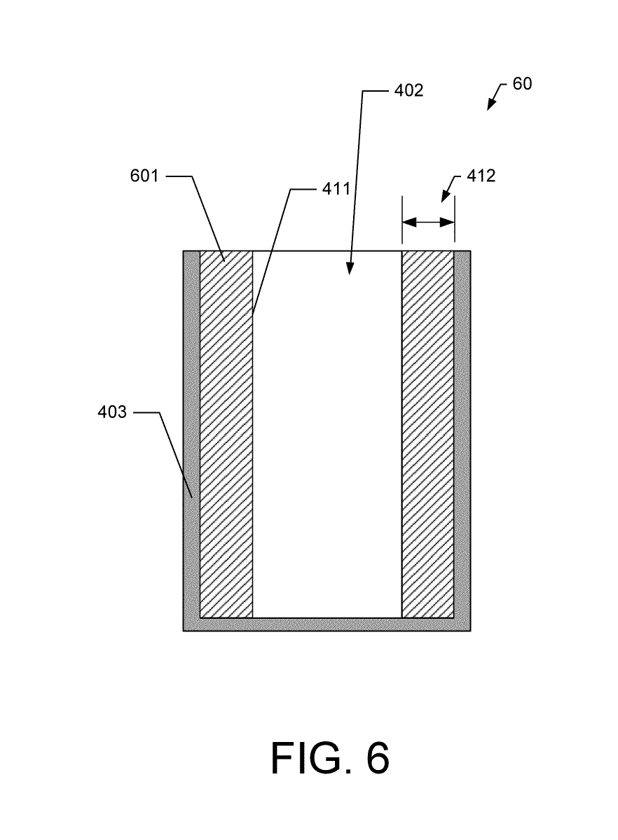

As shown in FIG. 6, a cavity 402 is formed with in the charge 401 by an elongated structure, such as an internal packing tube 405. In one aspect, the packing tube 405 is positioned within the crucible 403 prior to the addition the charge, while in another aspect; the packing tube is used to bore through the charge previously deposited in the crucible. While the packing tube 405 is disposed within the charge 401, the charge is compressed to form a porous charge body 601 that will retain its structure after removal of the packing tube 405. In one embodiment, the charge 401 is compressed linearly downward along an axis parallel to a central axis 408 of the crucible, as generally indicated by 410. In another embodiment, the charge 401 is compressed outward radially. This may be accomplished by manipulation of the packing tube 405. In other embodiments, the charge 401 may be compacted by a combination of linear and radial forces. The amount for force necessary to compress the charge 401 is dependent, at least in part, upon the particle size composition of the charge and may vary between embodiments.

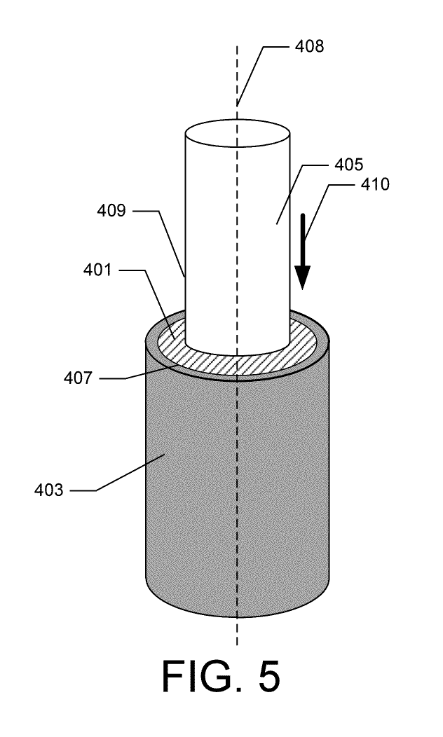

By way of example and not limitation, in one particular embodiment, approximately 1.5 kg of AlN powder mixed with carbon powder as to be used as the chemical driving agent that enhances volumetric expansion charge 401 is loaded inside a hollow crucible 403 having an internal diameter of approximately 6 inches about an internal packing tube 405 having a diameter of approximately 3 inches. The packing tube 405 is positioned within the crucible along a central longitudinal axis 408 of within the crucible, as shown in FIG. 5.

The charge 401 is compressed between the interior wall 407 of the crucible 403 and the external surface 409 of the packing tube 405. The powder charge 401 is pressed, at least a sufficient amount, for the charge to retain its shape and define the cavity 402, after the internal packing tube 405 is removed. The result is a charge body 601 having internal surfaces 411 that define the internal cavity 402. In other embodiments, other combinations of the diameters for the crucible 403 and the packing tube 405 may be used to create charge bodies of any desired thickness 412.

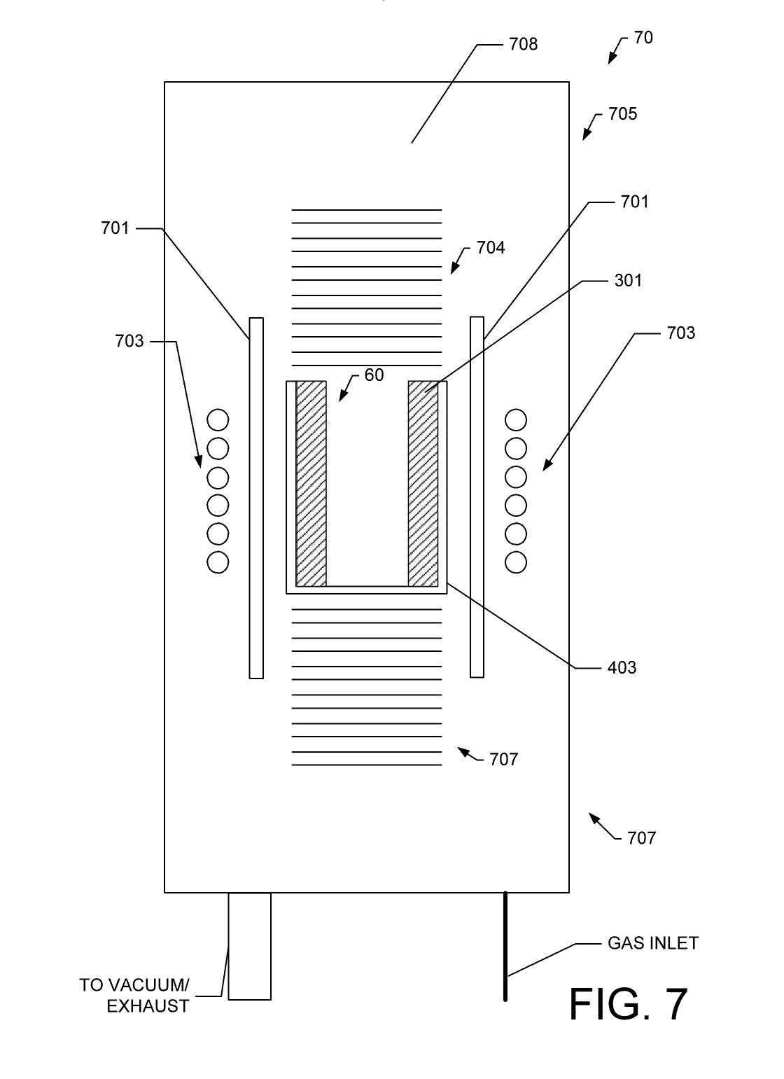

The crucible 402 including the charge body 601 (hereinafter referred to as packed crucible 60) is placed in a reactor 70, as shown in FIG. 7. In one embodiment, the reactor 70 is a high temperature induction reactor. In other embodiments, any suitable reactor capable of generating thermal gradients from the exterior to the interior of the packed crucible may be used. The reactor 70 can be heated using any type of suitable heating including but not limited to resistive heating plasma heating, or microwave heating. The precise layout and configuration of reactor components may vary accordingly.

By way of example and not limitation, one embodiment of the reactor 70 uses induction heating. In this embodiment, the packed crucible 60 is heated by a susceptor 701 positioned within a radio frequency induction field generated by the radio frequency induction coil 703. The susceptor 701 can be composed of any suitable and susceptible material, such as tungsten (W), for example. The reactor 70 also includes thermal insulation 704 positioned at the top 705 and bottom 707 portions of the reactor interior 708 moderate the thermal fields with the reactor interior. The thermal fields with the reactor 70 are also controlled and or modified by the positioning of the susceptor 701 within the reactor and the length, coil-to-coil gaping, and positioning of the radio frequency induction coil 703.

Prior to heating the crucible body 60, the reactor 70 may be evacuated to vacuum pressures, backfilled, purged, and evacuated again. In one embodiment using a charge body 601 composed of AlN, the reactor is evacuated to a vacuum at or below 1×10⁻² torr, backfilled/purged with nitrogen, and then evacuated again to a vacuum at or below 1×10⁻² torr. In this embodiment, the crucible body 601 is heated under vacuum to approximately 1700° C. for approximately 2 hours. In one aspect, this initial heating is used to sinter the AlN charge body 601.

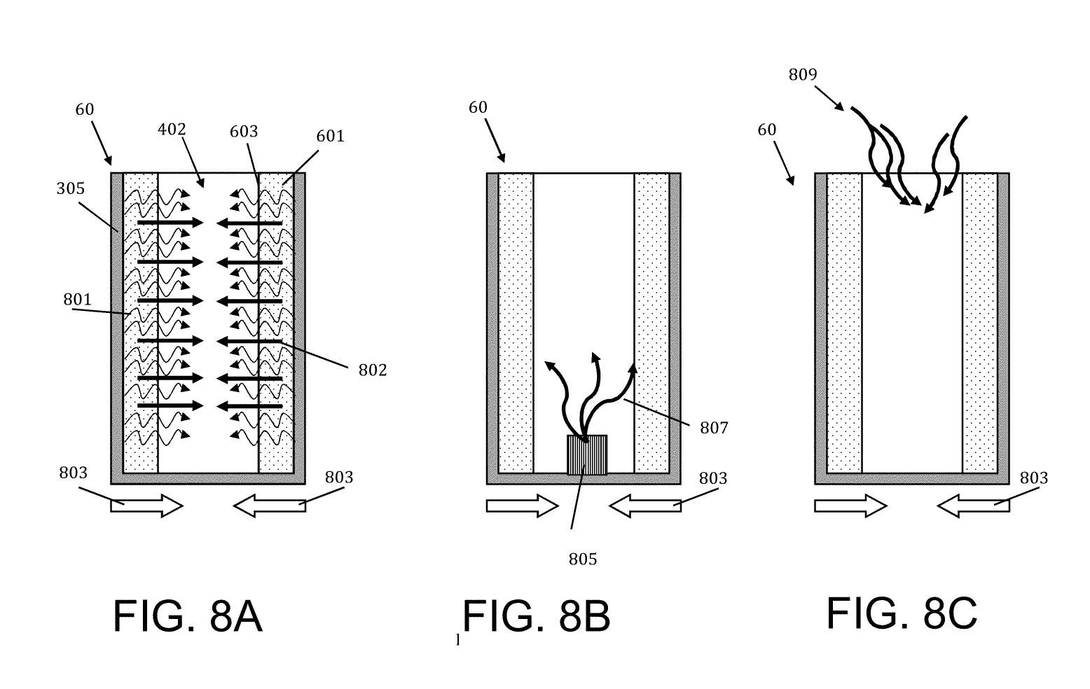

After this initial heating, the reactor 70 is backfilled with nitrogen to a pressure of approximately 980 torr, in one embodiment. The temperature of the crucible body 601 is then increased to 2100-2450° C. over a period of approximately one hour and allowed to soak at 2100-2450° C. for approximately 30 hours. During this soaking period, Al and N disassociate from the exterior wall 603 of the AlN charge body 601, as generally indicated by 801, along with the chemical driving agent 802, as shown in FIG. 8. A driving force 803, determined, at least in part, by the chemical concentration and the temperature gradient across the AlN charge body 601, is established inside the crucible 603 and through the AlN charge body 601, such that the disassociated Al and N diffuse through the porous AlN charge body the hollow internal cavity 402.

In various aspects, the thermal and chemical driving forces 803 are controlled by the internal thermal fields as moderated by the thermal insulation 705, the susceptor 701 placement and the characteristics of the induction coil 703, such as placement, coil length, and coil-to-coil gaping, shown in FIG. 7. The driving forces 803 are also controlled by the particle size of the charge body 601 and the charge body wall thickness 412, as indicated in FIG. 4. For embodiments, using an AlN charge body 60, Al and N and the carbon chemical driving agent are diffused through the AlN charge powder to the internal surface 411 of the charge body where freely nucleated AlN crystallization occurs and enhances volumetric expansion of the crystals 903. The particle size and packing density of the AlN charge body and chemical driving agent 601 affect the initial nucleation and subsequent growth of AlN crystals on the internal surface 411.

By way of example, after soaking for approximately 30 hours, the temperature of the packed crucible 30 is decreased to below 1000° C. over a period of one hour and allowed to rest and cool to near room temperature for around three hours. After the cooling period, the reactor is evacuated to a vacuum below approximately 1×10⁻² torr and backfilled/purged with nitrogen until an approximate atmosphere pressure is reached and the packed crucible 30 is removed.

In various embodiments, a precursor compound or compounds that will produce the desired chemical driving agent or agents in situ maybe used to promote preferential volumetric growth. For example, Gases, solids, open porous volume foams, powders, liquids, phase changing systems, or any other volatile or nonvolatile compound containing the desired chemical driver agent elements can be used, including oxides. As shown in FIG. 8B, a solid chemical driving agent source or precursor 805 may be placed in the packed crucible 60. During the growth process according to one embodiment, the solid chemical driving agent source or precursor 805 may sublimate or otherwise transition to a gaseous phase as indicated by 807. Alternatively, as shown in FIG. 8C, a gaseous chemical driving agent, may be directly introduced into the crucible, as indicated by 809.

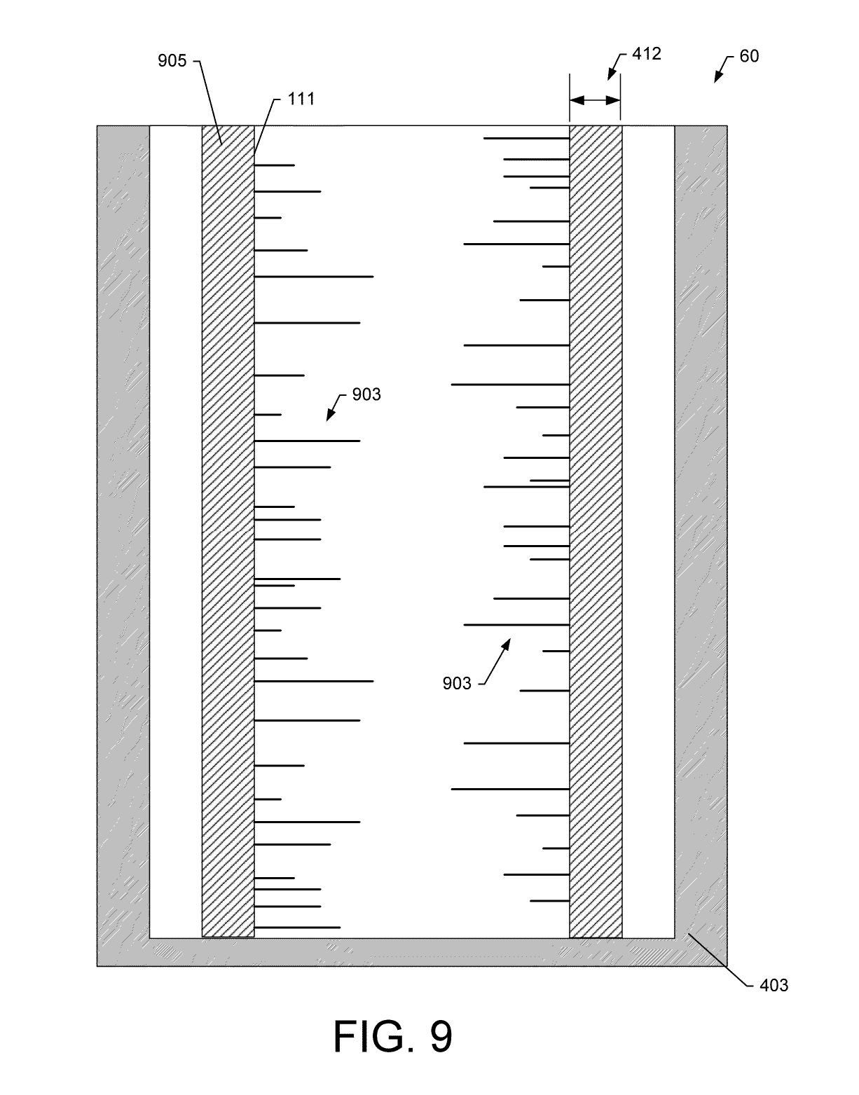

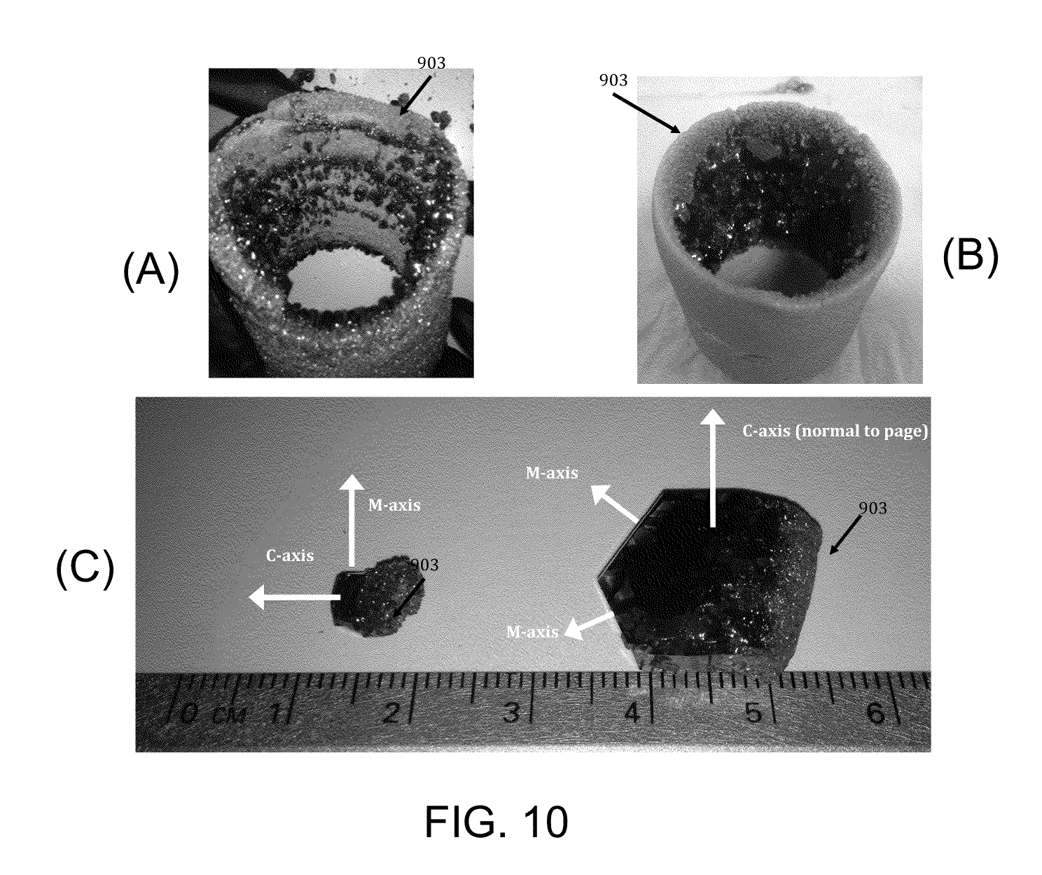

As shown in FIGS. 9 and 10, the packed crucible 60 now contains a depleted and crystallized AlN body 905 having a smaller wall thickness 412 as compared to the AlN charge body 601 prior to heating. The depleted and crystallized AlN body 905 also includes AlN crystals 903, freely nucleated on the internal surface 411 of the depleted body 905. By way of example and not limitation, approximately 1 to 500 crystals 903, as shown in FIG. 10, may be are produced simultaneously. The produced crystals 903 range in size from 1-30 mm in diameter. In other embodiments, larger and/or smaller crystals may be produced by varying the composition and packing density of the charge body 601, by varying the concentration of chemical driving agents and by varying the operation of the reactor 60.

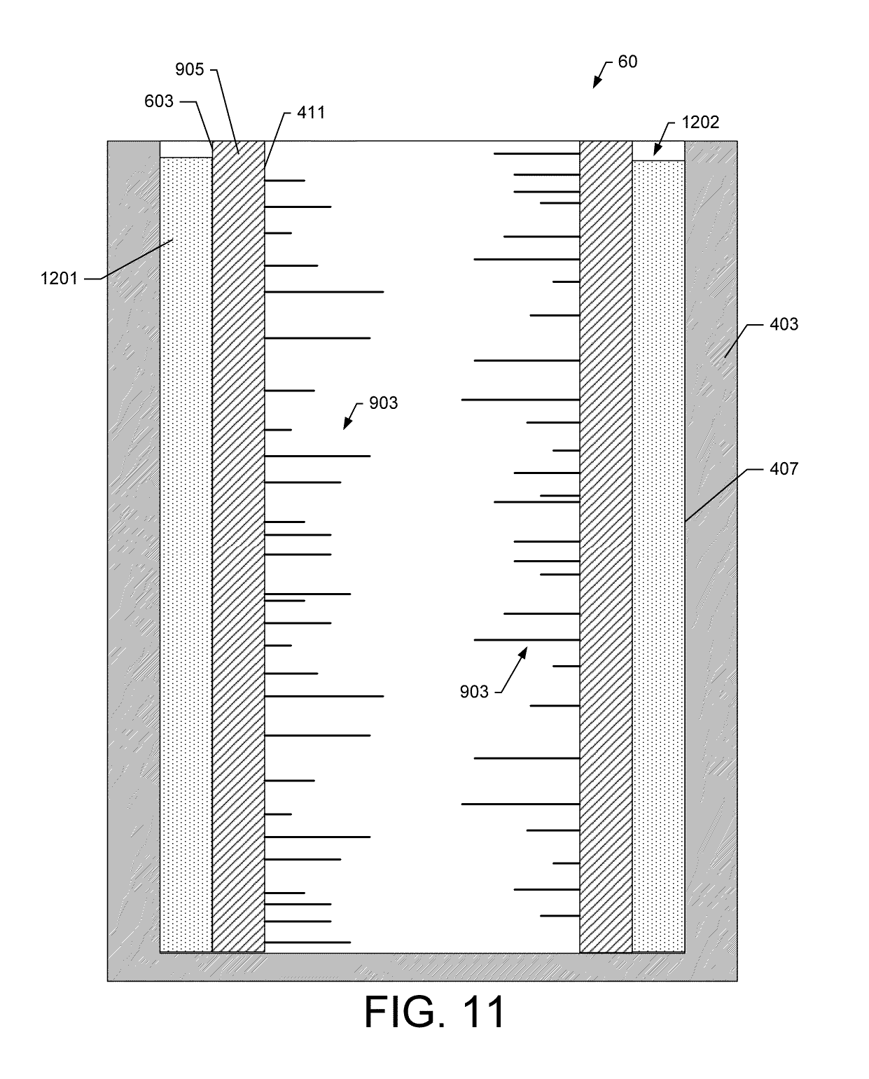

In one embodiment, the packed crucible 60 can be recharged with additional AlN powder and chemical driving agents 1201, as shown in FIG. 11. As shown, additional AlN powder and chemical driving agents 1201 may be packed and compressed in the space 1202 between the interior wall 407 of the crucible 403 and the external surface 603 of the depleted AlN body 905. The crucible 403 is then placed into the reactor 70 and the process as previously described is repeated. In various embodiments, the process of recharging the depleted charge body 905 and reinitiating diffusion to further crystal growth may be repeated to increase the crystal size as desired.

The nucleation of the crystals grown may be further controlled by various configurations of the charge body 601 or the use of additional features such as the use of multiple chemical driving agents. In one embodiment, the nucleation of crystals grown from an AlN charge body may be modified by the use of a charge body having at least one layer composed of particles that differ from the particle size of an adjacent layer with different chemical driving agents in each layer. For example, an AlN body 601 may be composed of two particle sizes with carbon mixed within particles of one size and indium mixed within the particles of the second size. In this example, a single layer, similar to layer 1203, as shown in FIG. 9, is composed of particles that differ in size from the remainder of the AlN body 601. In one aspect, the particles of the layer 1203 are a chemical driving agent that enhances volumetric expansion and a size that enhances nucleation, while the remaining particles are chemical driving agents of a size and kind that reduce nucleation. The size of all the particles in the AlN body 601 permit internal diffusion between the particles of the enhanced nucleation layer and the remainder of the particles in the body. In this embodiment, the particle size and chemical driving agent mixed layer selected to enhance nucleation is a lower fraction of the total AlN body 601 composition. For example, the nucleation enhancing particles of layer 1203 may be AlN powder approximately 2 micron in diameter, while the remainder of the AlN body is composed of particles approximately 100 micron in diameter, where the 100 micron diameter particles account for approximately 90% of the total volume of the AlN charge body 601. In other embodiments, the distribution of the nucleation reducing particles is not uniform, yet still forms a majority of the particles of the charge body 601. For example, the particle size the nucleation reducing portion may be a random mixture or preferentially selected. In yet other embodiments, only one chemical driving agent that enhances volumetric expansion is used.

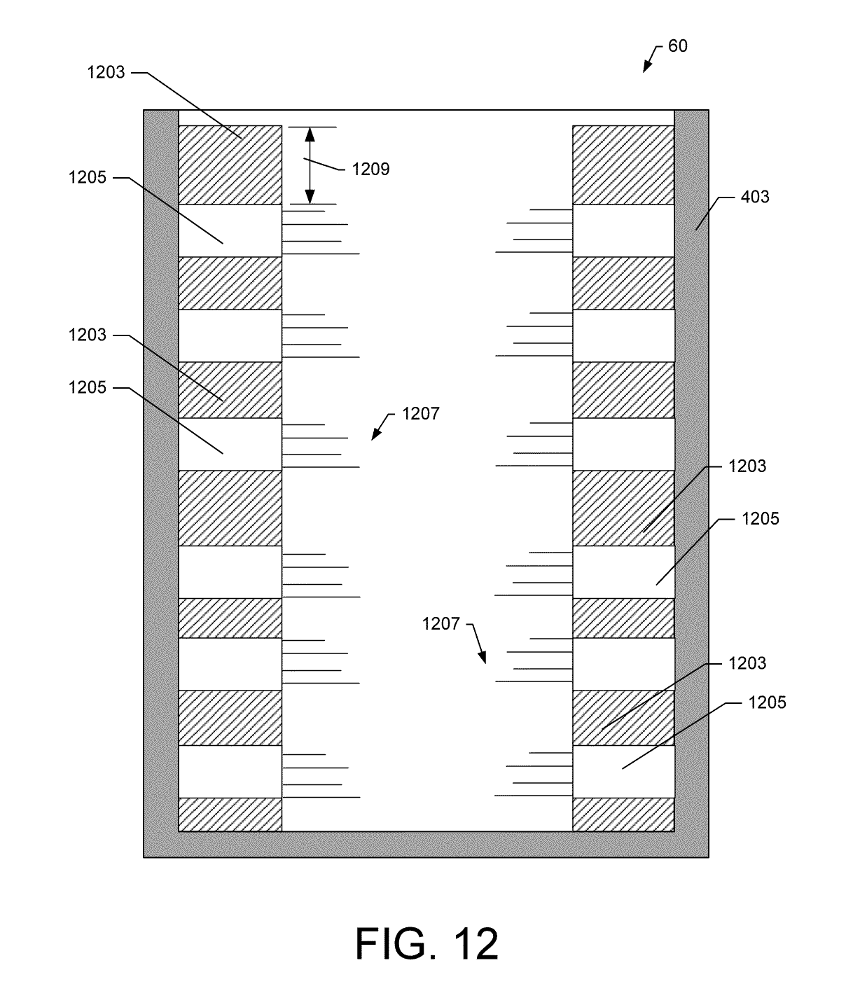

In another embodiment, as shown in FIG. 12, the AlN body may be composed of multiple charge layers, including alternating nucleation enhancing layers 1203 and nucleation reducing layers 1205. In this embodiment, the sizes of all the particles in the AlN body 601 are selected to permit internal diffusion between the particles and layers 1203 and 1205. In this embodiment, the nucleation enhancing layers 1203 provide ideal nucleation sites to grow crystals 1207, while the particles of the nucleation reducing layers 1205 are diffused to provide, at least a portion, of the source Al and N species for crystal growth. As shown, in one embodiment, the multiple charge layers 1203 and 1205 are arranged horizontally in relation to the internal cavity 402. In some embodiments, the layers 1203 and 1205 may alternate and have approximately equal thickness 1209, while in other embodiments, the arrangement and thickness of the layers 1203 and 1205 may vary. Additionally, in some embodiments, the ratio of layers and overall particle distribution between the layers may be equal, while in others the ratio and overall particle distribution may vary.

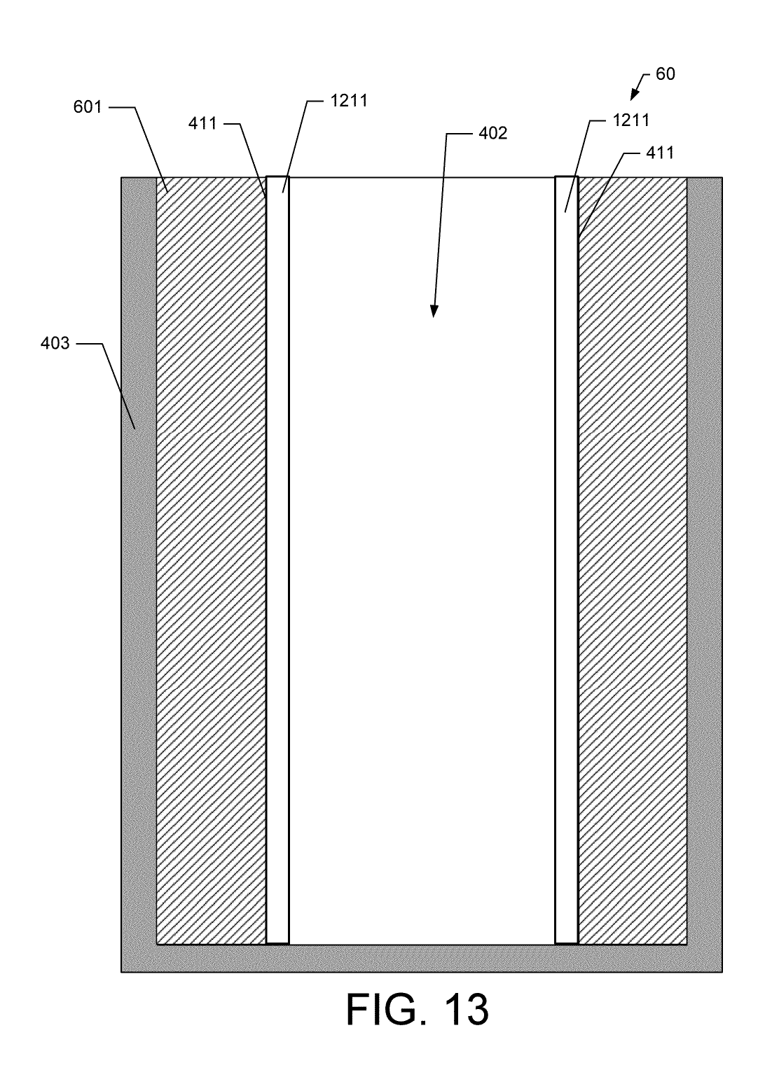

In yet another embodiment, shown in FIG. 13, an inert filler 1211 that does not react with the constituent species of the grown crystals may be disposed on or near portions of the interior surface 411 of the charge body 601 to modify the nucleation of crystals grown on the charge body. By way of example and not limitation, the inert filler 1211 may be a solid tungsten, zirconium, tantalum, niobium, molybdenum, or other solids that can withstand the temperatures within of the reactor without chemically reacting with the dissociating crystal constituents. In various embodiments, the inert filler 1211 may be shaped to physically interact with or modify the crystal growth. Additionally, the inert filler 1211 may be used to enhance or alternatively, retard crystal growth at nucleation sites on the interior wall 411 of the charge body 601.

In one embodiment, the inert filler may be a porous body 1301 that defines one or more holes, apertures, or slits to permit chemical driving agent gas diffusion and provide desired crystal growth locations. The porous body 1301 may be positioned to contact the interior surface 411 of the charge body 601 or may be disposed within the charge body and may include apertures that may be randomly positioned or arranged in a desired orientation. Additionally, the size of the apertures may be varied.

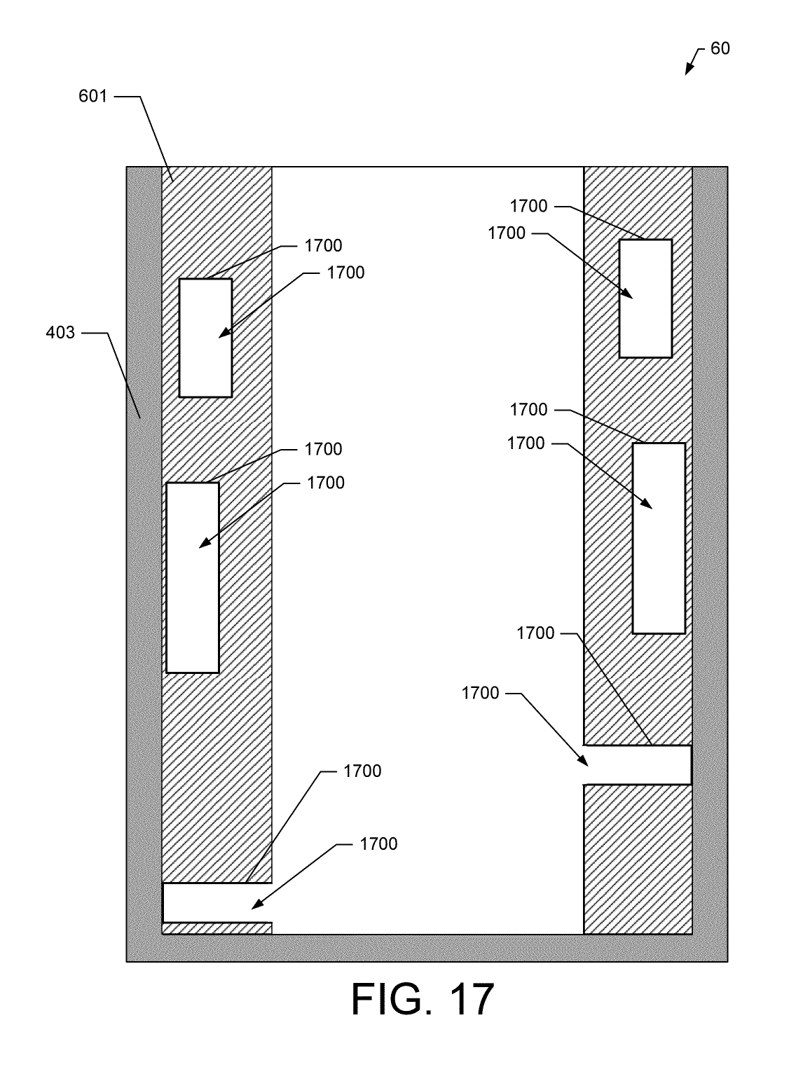

In one embodiment, as shown FIG. 17, the crystal nucleation may be controlled by the partial or full through-holes 1700 defined in the charge body 601. This can also be done using a tantalum or tungsten tube 1702 to ensure the partial or full through holes 1700 do not collapse under compression. In one particular, embodiment, the partial or full through holes are formed by the positioning the filler material in the charge body 601 prior to compression. In another embodiment, filler material to form the partial or full through holes is introduced after compression and formation of the charge body 601.

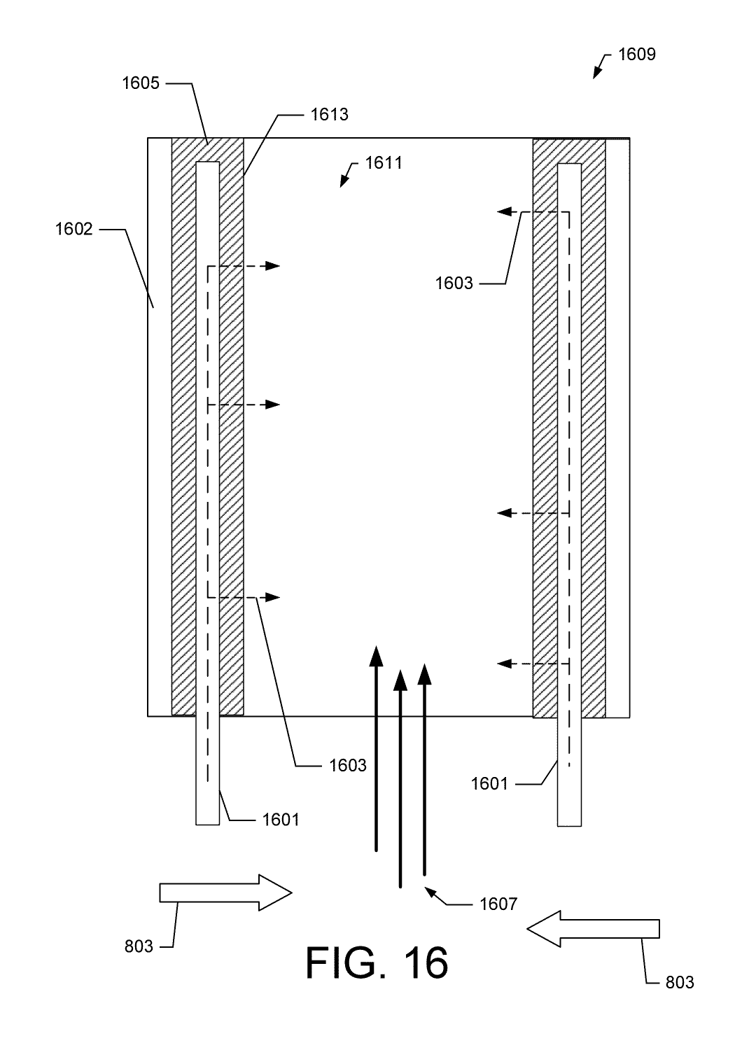

In various other embodiments, c-plane oriented AlN crystals may be grown using Aluminum Chlorides (AlClₓ) diffused through a substantially/sufficiently porous charge body 1605 of AlN powder which contacts cross-flowing ammonia (NH₃) and chemical driving agent gases. FIG. 16 is a partial cross-section view of a portion of a high temperature reactor 1609. As shown, an AlN charge powder having particles varying in size from about 0.1 microns to 1 mm is loaded inside a hollow crucible 1602 that includes or is configured to receive one or more gas inlet tubes 1601. In one aspect, the crucible 1602 is an open ended crucible, as shown. In one embodiment, up to 1.5 kg of the charge powder is packed around a packing tube, such as the packing tube 405, and compressed as previously described. As shown, the formed AlN charge body 1605 is formed around the gas inlet tubes 1601.

The crucible 1602 including the AlN charge body 1605 is placed in a high temperature reactor, such as an induction reactor, for example. In this example, a high temperature induction reactor, similar to the reactor 70 shown in FIG. 7 is evacuated, backfilled/purged with nitrogen and then evacuated again as previously described. In one embodiment, the crucible 1602 is heated under vacuum to about 1700° C. for about 2 hours to drive off native impurities and to sinter the AlN charge body. The reactor 1609 is backfilled with nitrogen to a pressure of approximately 980 torr. The crucible 1602 is then heated and maintained at a temperature between 1400-1900° C. for one hour or more and allowed to soak for approximately 15 hours. Aluminum Chloride (AlCl₃) 1603 is pumped into the gas inlet tubes 1601 to function as an Aluminum source. In addition, ammonia gas and chemical driving agents 1607 is allowed to flow through the open ended crucible 1602, where it functions as a nitrogen source and source for the chemical driving agent used for preferred volumetric expansion to contact the interior surface 1613 of the AlN charge body 1605.

A driving force 803, defined, at least in part, by the pressure of the AlCl 1603 gas is established inside the crucible and across the AlN charge body such that the AlCl gas driven to diffuse through the charge body and into the interior cavity 1611 of the crucible 1602. In one aspect, the diffusion of the AlCl is controlled by the pressure differential between the AlCl gas and the internal pressure of the reactor. The AlCl is diffused through the AlN charge body 1605 to the internal surface 1613 where the AlCl reacts with the NH3 and chemical driving agents to preferentially freely nucleated AlN crystals on the internal surface. In another aspect, the AlN powder particle size and packing density of the AlN charge body 1605 impact the initial nucleation and subsequent growth of AlN crystals on the internal sidewalls 1613. After eight hours, the crucible 1602 is cooled down to below 1000° C. over one hour and allowed to rest for around three hours. After such time the reactor is evacuated less than 1×10⁻² torr, backfilled/purged with nitrogen to atmosphere pressure, where the crucible 1602 is then removed. In this embodiment, approximately 50-500 crystals ranging in diameter from about eight mm to about fifteen mm are produced.

### C-Plane Oriented AlN Crystal Growth

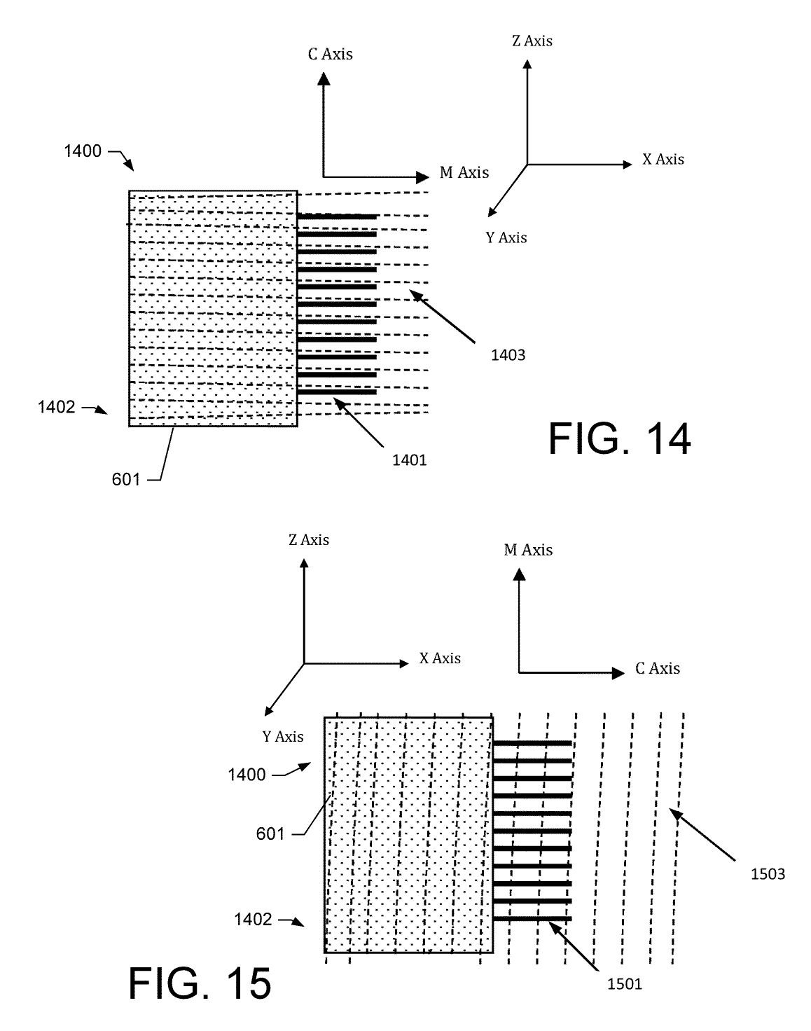

Referring now to FIG. 14, c-plane AlN crystals 1401 larger than 1-30 mm in diameter may be produced. According to one embodiment, large AlN crystals may be produced on the inside surface 411 of the AlN charge body 601 by adding in one or more chemical driving agents, such as carbon, and orienting isotherms 1403 within the charge body to align substantially parallel to the top portion 1400 and bottom portion 1402 of the AlN charge body. As shown, the c-plane of the AlN crystals aligns closely to the cooler isotherm lines 1403. In one aspect, when the temperature gradient between isotherm lines are sufficiently low (less than 20° C. per mm) growth in the z direction of the c-plane vs. the x-y plane is additional slowed in comparison to the use of a chemical driving agent alone. In this embodiment, relatively thin (i.e. less than 2 mm thick) c-plane AlN crystals can be produced with large diameter may be preferentially produced. Alternatively, a chemical driving agent can be used when the temperature variations between isotherms are not sufficiently low, so as to be negligible, or when the isotherms are not preferentially aligned for the desired crystal growth orientation.

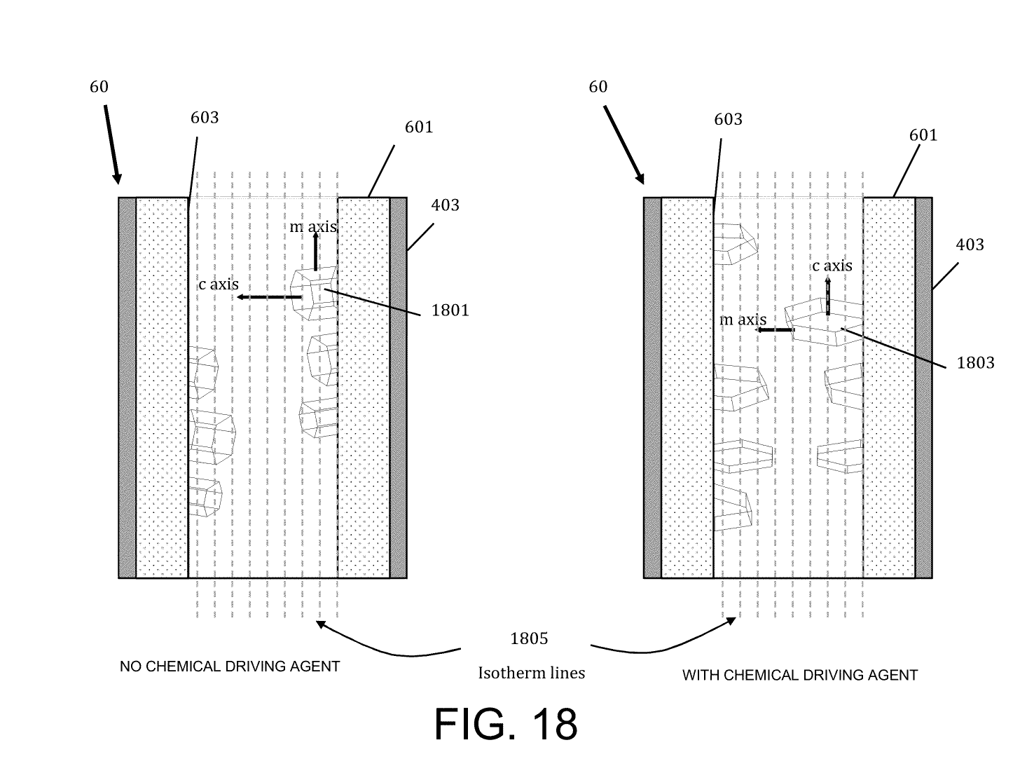

Referring now to FIG. 18, the isotherms 1805 are not preferentially aligned for c-plane platelet growth. As such, for the aluminum nitride body 1801, produced without a chemical driving agent, the c-axis aligns itself radially inside the crucible 60. The resulting crystals 1801 are not platelets. As shown in FIG. 18, the addition of a chemical driving agent, such as carbon for example, into the aluminum nitride body 601 preferentially causes aluminum nitride c-plane platelets 1803 to be produced even in an environment where the isotherms 1805 ordinarily would inhibit such growth.

In another embodiment, large c-plane oriented AlN crystals may be grown using a charge body 601 composed of a mixture of AlN and tungsten (W) powder with an external supply of carbon bearing gas. In this embodiment, c-plane AlN crystals larger than 1-30 mm in diameter are controllability grown on the interior surface of the AlN/W charge body using diffused Al and nitrogen through the porous charge body reacting with an atmosphere of carbon bearing gas. AlN powder having particles in range from about 0.1 microns to 1 mm in diameter is mixed with W powder having particles in a range from about 0.1 microns to 1 mm. The distribution of the AlN and the W powder can be a random mix or preferentially orientated. In one embodiment, the concentration of chemical driving agent gases can be varied during the growth to control the volumetric growth as the source AlN powder is depleted and the growth rate of the c-plane crystals changes with time.

In yet another embodiment, large c-plane oriented AlN crystals may be grown using a charge body 601 composed of a mixture of AlN and Aluminum (Al) powder and Al₂C₃ powder. In this embodiment, c-plane AlN crystals larger than 1-30 mm in diameter are controllability grown on the interior surface 411 of the AlN/W charge body using diffused Al and nitrogen through the porous charge body. AlN powder having particles in range from about 0.1 microns to 1 mm in diameter is mixed with Al powder having particles in a range from about 0.1 microns to 1 mm and Al₂C₃ powder having particles in a range from about 0.1 microns to 1 mm. The distribution of the AlN, the Al, and the Al₂C₃ powder can be a random mix or preferentially orientated. In one embodiment, similar to that described in reference to FIGS. 4-7, up to 1.5 kg of the AlN/Al/Al₂C₃/W powder mixture is added to the crucible 403 to form the charge body 601.

In various other embodiments, the reactor configuration shown in FIG. 16, may be used to produce c-plane oriented AlₓGa₍₁₋ₓ₎N crystals by diffusing aluminum chlorides (AlClₓ) and gallium chlorides (GaClₓ) through a porous body. The porous body is composed of a mixture of AlN powder, GaN powder, Magnesium (Mg) powder and Indium (In) powder, where the combination of Mg and In functions as a chemical driving agent to enhance volumetric growth. The AlN/GaN/MG/In powder mixture is packed and compressed in to crucible as previously described in relation to FIGS. 4-7. AlClₓ gas(es) and GaClₓ gas(es) are then pumped through the gas inlet tubes 1601 to facilitate the diffusion and subsequent nucleation of the Al and Ga species along with N species on the interior surface 1613 of the AlN/GaN/MG/In charge body.

Similarly, in another embodiment c-plane oriented GaN crystal may be grown via the diffusion of Ga and N species through a porous charge body composed of a GaN/In powder mix, where the In powder functions as an a chemical driving agent to enhance volumetric growth.

### M-Plane Oriented AlN Crystal Growth

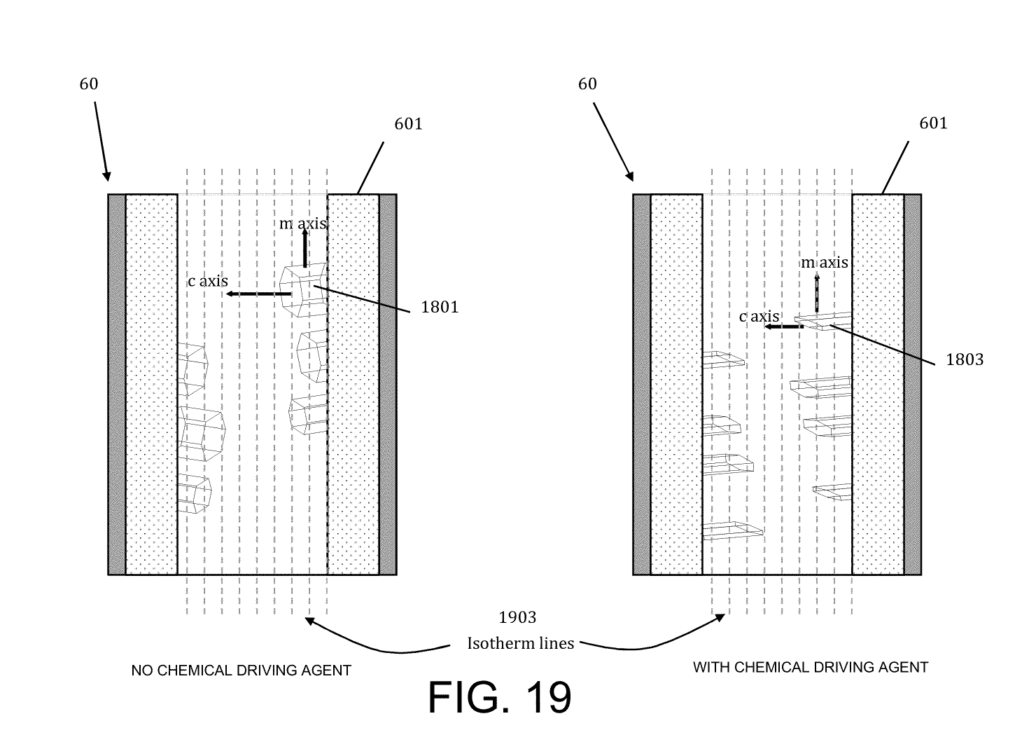

Referring now to FIG. 15, m-plane AlN crystals 1501 larger than approximately 1-50 mm in diameter may be produced. According to one embodiment, large AlN crystals may be produced on the inside surface 411 of the AlN charge body 601 by adding a chemical driving agent with or without orienting isotherms 1503 within the charge body to be sufficiently perpendicular to the top portion 1400 and bottom portion 1402 of the AlN body. As the c-plane of the AlN crystals are preferably produced using chemical driving agents, m-plane AlN crystals are produced using chemical driving agents such as S or B. In one aspect, this growth can be further enhanced when the temperature gradient between isotherm lines is sufficiently low (i.e. less than 20° C. per mm) growth in the X-Y direction of the M-plane is increased in comparison to the growth in the Z direction normal to the m-plane yielding a larger m-plane surface. In one embodiment the chemical driving agent employed is diborane gas. Alternatively, a chemical driving agent can be used when the temperature variations between isotherms are not sufficiently low so as to be negligible, or when the isotherms are not preferentially aligned for the desired crystal growth orientation. Now referring to FIG. 19. The isotherms 1903 are preferentially aligned for m-plane platelet growth but growth expansion in the c-plane will occur regardless. Thus, where an aluminum nitride body 1801 is produced without a chemical driving agent, the c-axis aligns itself radially inside the crucible 60. The resulting crystals 1801 have good m-plane facets but do not have large usable m-planes and are not platelets. The addition of chemical driving agents, such as boron, for example, into the aluminum nitride body 601 causes aluminum nitride m-plane platelets 1803 to be preferentially produced by reducing the growth in the c-plane.

The embodiments disclosed herein may be used to manufacture c-plane oriented AlxGa1-xN crystals via HVPE growth using AlClx, GaClx, NH₃, and a hydrocarbon gas as a chemical driving agent that is used to control preferential volumetric growth. Similarly, the systems and methods may be used to manufacture m-plane oriented AlₓGa₁₋ₓN crystal with HVPE growth using AlClₓ, GaClₓ, NH₃, and a boron gas as a chemical driving agent that is used to control preferential volumetric growth. Additionally, the embodiments disclosed herein may be used to manufacture c-plane oriented Gallium nitride crystals using NH3 and cyanide gas, used as an agent that is used to control preferential volumetric growth, diffused through a first substantially/sufficiently porous plate of Al₂O₃ and a second substantially/sufficiently porous body of Gallium nitride

### Bulk C-Plane/M-Plane Alternating AlN Crystal Growth

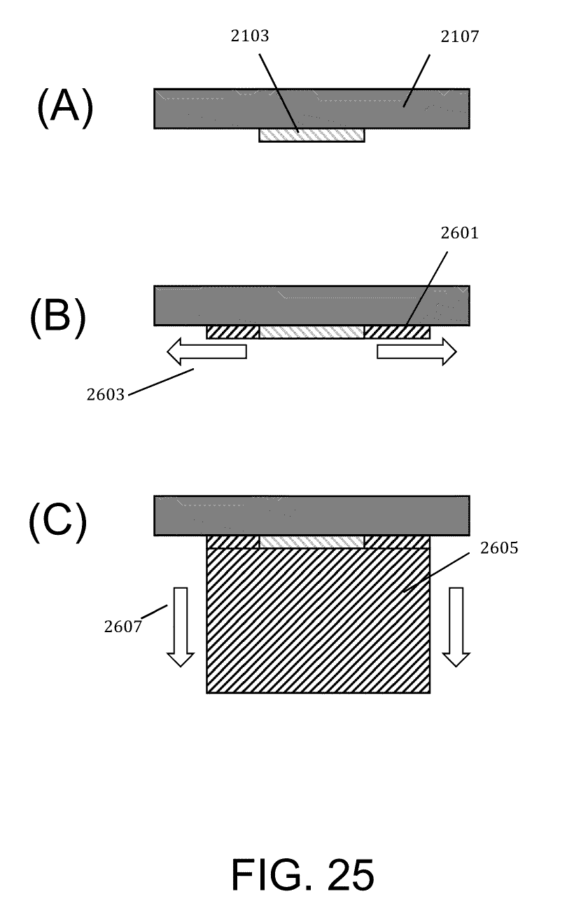

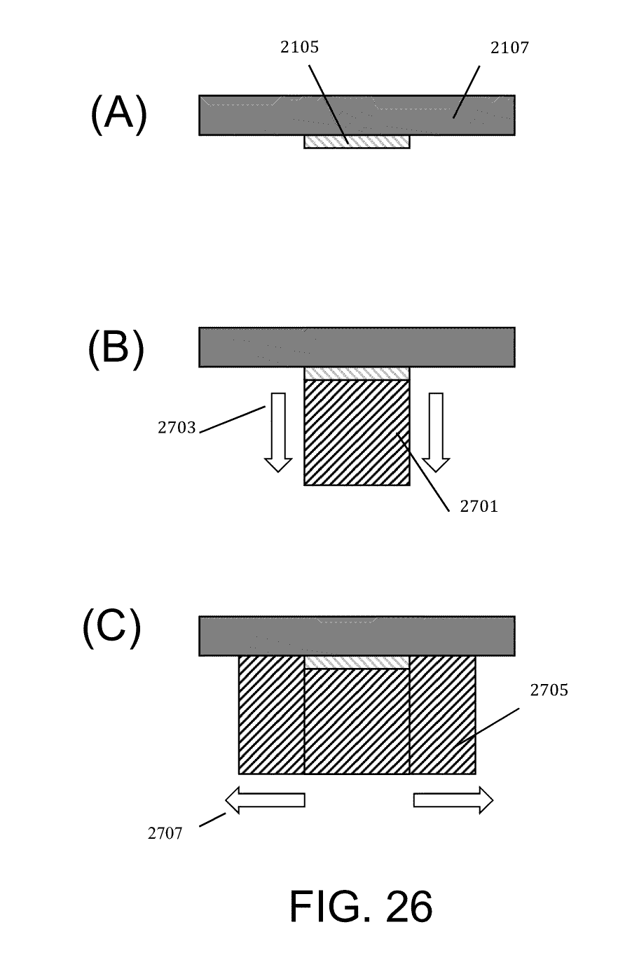

Referring now to FIGS. 20-28, the volumetric expansion systems and methods disclosed herein can be used in conjunction with other crystal growth techniques. Where the use of a chemical driving agent to preferentially volumetrically expand the crystal is toggled on and off or grated during the growth. This can allow for the preferential volumetric expansion in one plane until significant size/volumetrically expanded has been accomplished, then changing the growth direction two one that preferential volumetric expanses a different crystal plane. This can be done by reducing or eliminating one agent allowing non-preferentially volumetrically expansion or by introducing second agent that will preferentially volumetrically expanded the crystal in another plane. For example a chemical driving agent can be added to standard sublimation growth methods of AlN as to preferential volumetric expansion out a seed crystal. Aluminum nitride powder is mixed with a chemical driving agent forming a charge 2103 and place at the bottom of crucible 2101 the crucible is sealed with a lid 2107 where a seed crystal 2105 is attached there to provide a gross surface for the resulting aluminum nitride. A thermal gradient 2305 is provided from the bottom, hotter, to the top. cooler. Such as to promote transport of aluminum nitride vapor 2503 from the source charge 2103 to the seed 2105. The addition of the chemical driving agent can preferentially volumetrically expand the crystal 2601 or 2701 either parallel 2603 or horizontal 2703 to the seed face, as shown in FIGS. 25-26. As the concentration of the chemical driving agent is depleted, natural growth resumes 90° to the previous growth. For example, growth continues horizontal 2607 to the seed face as expected before it was preferentially volumetrically expanded parallel, and parallel 2707 to the seed face as expected before it was preferentially volumetrically expand horizontally, thus providing an 3-D enlarged crystal 2605 or 2705, as shown in FIGS. 25-26. If a gaseous chemical driving agent is used, the concentration of the chemical driving agent can be controlled, increased, decreased, and/or turned off once desired volumetric expansion has been achieved. In other embodiments, two different chemical driving agents are cycled. First one chemical driving agent is used to volumetrically expand the crystal in the c-plane, while the second chemical driving agent is used to volumetrically expand the crystal in the m-plane. The chemical driving agents can be cycled once or back and forth multiply times. One chemical driving agent can be used for an extended period of time then turned off and the second agent can be employed in the crystal growth to volumetrically expand the crystal in another plane.

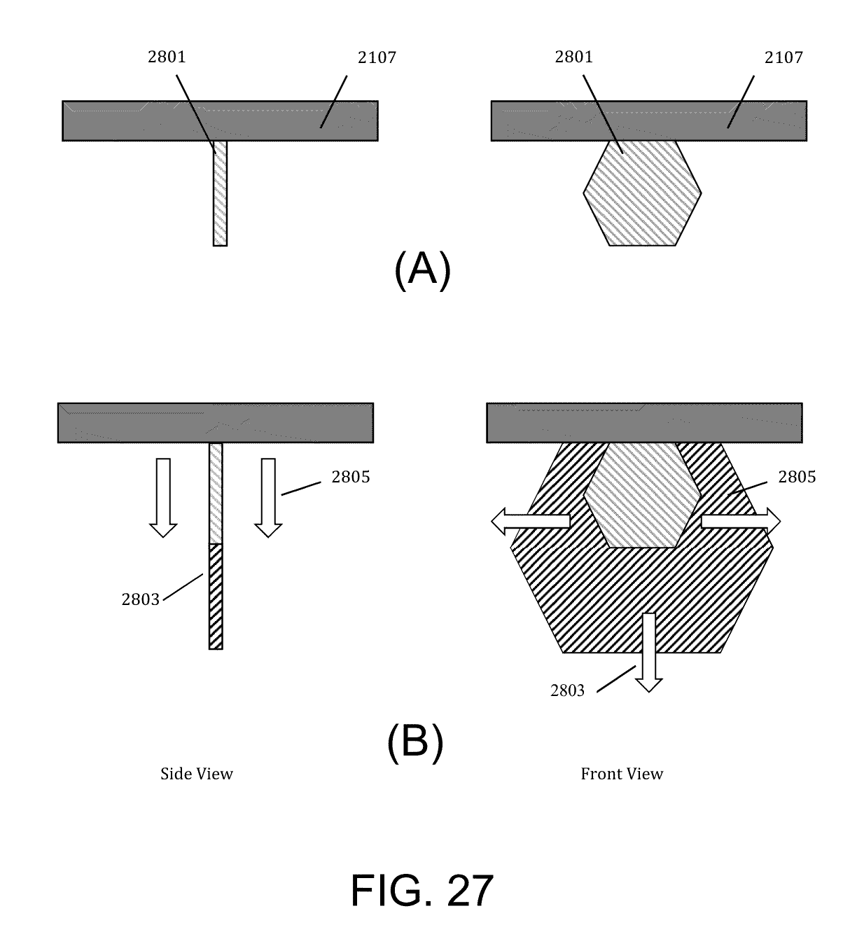

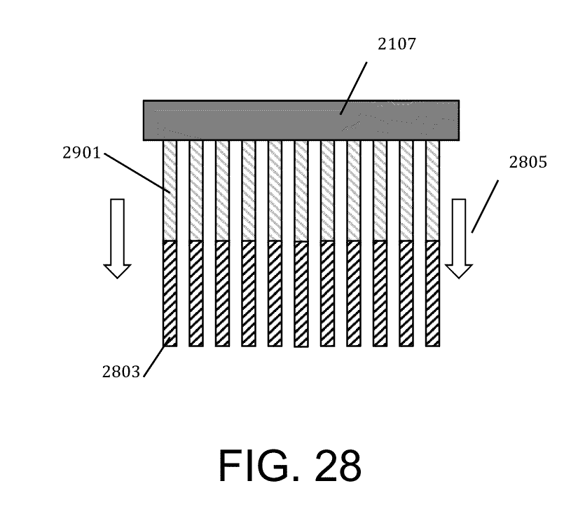

Alternatively in another embodiment, shown in FIG. 27, a seed crystal 2801 used in standard sublimation can be turned 90° in the crucible 2101 and attached to the top lid 2107. A chemical driving agent can be employed to expand the seed volumetrically as indicated by 2805, resulting in a seed 2803 of larger diameter with very little increase in thickness. In another embodiment, as shown in FIG. 28, multiple seeds 2901 can be attached to the top lid during a single growth process. The method of this embodiment can be further enhanced by controlling the isotherms inside the crucible and/or using a chemical driving agent. Similar to the growth shown in FIG. 27, the multiple seeds 2901 may also be rotated after an initial growth process to encourage growth in diameter without large increases in thickness.

Those skilled in the art will appreciate that variations from the specific embodiments disclosed above are contemplated by the invention. The invention should not be restricted to the above embodiments, but should be measured by the following claims.

1. A method of preferably volumetrically enlarging a group III-V nitride crystal comprising:
providing a crystal growth structure;
providing a crystal growth constituent, where the crystal growth constituent grows the group III-V nitride crystal on the crystal growth structure;
providing a chemical driving agent, where the chemical driving agent enhances or limits crystal growth on a particular plane of the group III-V nitride crystal.

2. The method of claim 1 where the group the III-V nitride crystal is substantially a single crystal.

3. The method of claim 1 where the group III-V nitride crystal comprises nitrogen and at least one species of Al, Ga, and In.

4. The method of claim 3 where the group III-V nitride crystal has a formula of AlₓIn_{y}Ga_{(1-x-y)}N, where 0≧x≦1, 0≧y≦1, x+y+(1−x−y)≠1.

5. The method of claim 1 where the chemical driving agent comprises carbon.

6. The method of claim 1 where the chemical driving agent comprises boron.

7. The method of claim 1 where the chemical driving agent comprises at least one of indium, gallium, sulfur, or bismuth.

8. The method of claim 7, where the chemical driving agent further comprises carbon, boron, or both.

9. The method of claim 1 where the chemical driving agent comprises a gas.

10. The method of claim where the chemical driving agent is provided by sublimating a solid.

11. The method of claim where the solid is sublimated in situ to provide a gaseous chemical driving agent.

12. The method of claim 1 where one or more temperature gradients are used in conjunction with the chemical driving agent to enhance or limit crystal growth on a particular plane of the group III-V nitride crystal.

13. The method of claim 1, where the crystal growth structure is a substrate.

14. The method of claim 1, where the crystal growth structure is a seed.

15. The method of claim 1, where the crystal growth structure is a previously grown-crystal.

16. The method of claim 15, where the chemical driving agent enhances growth of the previously grown-crystal from a first diameter to a second diameter without a corresponding growth in thickness.

17. The method of claim 15, where the chemical driving agent enhances growth of the previously grown-crystal from a first diameter to a second diameter without inducing thermal stress into the previously grown-crystal.

18. The method of claim 17, where the chemical driving agent limits thermal stress.

19. The method of claim 1 where the particular plane is a c lattice plane.

20. The method of claim 1 where the particular plane is an m lattice plane.

21. The method of claim 1 where the group III-V nitride crystal is a platelet.

22. A method of preferably volumetrically enlarging a group III-V nitride crystal comprising:
providing a crystal growth structure;
providing a crystal growth constituent, where the crystal growth constituent grows the group III-V nitride crystal on the crystal growth structure;
providing a chemical driving agent, where the chemical driving agent enhances or limits the mobility of a crystal growth constituent adatom at a growth surface of the group III-V nitride crystal.

23. The method of claim 22, wherein the crystal growth structure is disposed within in a reactor system, and the chemical driving agent alters the surface growth kinetics of the reactor system.

24. A method for growing and preferably volumetrically enlarging a group III-V nitride crystal, the system comprising:
providing a powder to an annular-shaped cavity of a crucible, the annular shaped cavity defined by an interior surface of the crucible and a packing tube removably disposed in the crucible, and where the powder comprises a distribution of particle sizes of at least one constituent species of the group III-V nitride crystal;
compressing the powder to form a charge body;
removing the packing tube to form a charge body cavity, the charge body comprising an exterior surface and an interior surface defining the charge body cavity;
heating the crucible to sinter the charge body, wherein heating the crucible further induces a thermal driving force across the charge body;
providing a chemical driving agent;
soaking the crucible and the charge body at a temperature sufficient to diffuse the at least one constituent species of the group III-V nitride crystal from the exterior surface to the interior surface of the charge body, where the at least one constituent species of the group III-V nitride crystal freely-nucleates in the interior surface to grow the group III-V nitride crystal in the interior cavity; and
wherein the chemical driving agent enhances or limits crystal growth of the group III-V nitride crystal on a particular plane of the group III-V nitride crystal.

25. A system for growing and preferably volumetrically enlarging a group III-V nitride crystal, the system comprising:
a reactor;
a crucible;
a chemical driving agent source;
a sintered porous body disposed with in the crucible, the sintered porous body comprising an exterior surface, an interior surface defining an interior cavity and at least one constituent species of the group III-V nitride crystal;
wherein the reactor heats the crucible to form a thermal driving force across the sintered porous body;
wherein the thermal driving force diffuses the at least one constituent species of the group III-V nitride crystal from the exterior surface to the interior surface;
wherein the at least one constituent species of the group III-V nitride crystal freely-nucleates in the interior surface to grow the group III-V nitride crystal in the interior cavity; and
wherein the chemical driving agent enhances or limits crystal growth of the group III-V nitride crystal on a particular plane of the group III-V nitride crystal.
